(19) United States
(12) Patent Application Publication
(10) Pub. No.: US 2016/0079070 A1
(43) Pub. Date: Mar. 17, 2016

(54) METHOD OF MANUFACTURING SEMICONDUCTOR DEVICE AND SUBSTRATE PROCESSING APPARATUS

(71) Applicant: HITACHI KOKUSAI ELECTRIC INC., Tokyo (JP)

(72) Inventors: Arito OGAWA, Toyama-shi (JP); Yuji TAKEBAYASHI, Toyama-shi (JP)

(73) Assignee: HITACHI KOKUSAI ELECTRIC INC., Tokyo (JP)

(21) Appl. No.: 14/841,764

(22) Filed: Sep. 1, 2015

(30) Foreign Application Priority Data
Sep. 12, 2014 (JP) 2014-186029

(51) Int. Cl. H01L 21/285; C23C 16/52; H01L 21/02; C23C 16/455

(52) U.S. Cl. CPC H01L 21/28506; C23C 16/455; C23C 16/52; H01L 21/02271

(57) ABSTRACT

A method of manufacturing a semiconductor device includes forming a film on a substrate by performing a predetermined number times a cycle including: supplying a first process gas to the substrate; and supplying a second process gas to the substrate, wherein the act of supplying the first process gas and the supplying the second process gas are performed in a state where the substrate is maintained at a predetermined temperature of room temperature or more and 450 degrees C. or less; and a third process gas, which reacts with byproducts produced by a reaction of the first process gas and the second process gas, is supplied to the substrate simultaneously with at least one of the act of supplying the first process gas or the act of supplying the second process gas.

### CROSS-REFERENCE TO RELATED APPLICATIONS

This application is based upon and claims the benefit of priority from Japanese Patent Application No. 2014-186029, filed on Sep. 12, 2014, the entire contents of which are incorporated herein by reference.

### TECHNICAL FIELD

The present disclosure relates to a method of manufacturing a semiconductor device and a substrate processing apparatus.

### BACKGROUND

In semiconductor devices including transistors such as metal-oxide-semiconductor field effect transistors (MOSFETs), the high integration and high performance thereof have been desired and applications of various types of films are being considered. In particular, metal films have been used as gate electrodes of MOSFETs or capacitor electrode films of DRAM capacitors in the related art.

However, when a thin film such as a metal film is formed on a substrate, byproducts may be generated, and these byproducts may cause hindering of a film forming reaction. Further, this may result in a decrease in a film forming rate, a degradation of film quality such as an increase in resistivity, or the like.

### SUMMARY

The present disclosure provides some embodiments of a technique capable of discharging byproducts, which are produced when a thin film is formed on a substrate, to the outside of a process chamber.

According to one embodiment of the present disclosure, there is a method of manufacturing a semiconductor device, including forming a film on a substrate by performing a predetermined number times a cycle including: supplying a first process gas to the substrate; and supplying a second process gas to the substrate, wherein the act of supplying the first process gas and the act of the supplying the second process gas are performed in a state where the substrate is maintained at a predetermined temperature of room temperature or more and 450 degrees C. or less; and a third process gas, which reacts with byproducts produced by reaction of the first process gas and the second process gas, is supplied to the substrate simultaneously with at least one of the act of supplying the first process gas or the act of supplying the second process gas.

### BRIEF DESCRIPTION OF THE DRAWINGS

FIG. 1 is a schematic view illustrating a configuration of a processing furnace of a substrate processing apparatus used in a first embodiment of the present disclosure, in which the processing furnace portion is illustrated in a longitudinal sectional view.

FIG. 2 is a cross-sectional view taken along line A-A of FIG. 1.

FIG. 3 is a block diagram illustrating a configuration included in a controller of the substrate processing apparatus illustrated in FIG. 1.

FIG. 4 is a diagram illustrating a time chart of a film forming sequence according to the first embodiment of the present disclosure.

FIG. 5 is a diagram illustrating a time chart of a film forming sequence according to a second embodiment of the present disclosure.

FIG. 6 is a diagram illustrating a time chart of a film forming sequence according to a third embodiment of the present disclosure.

FIG. 7 is a diagram illustrating a time chart of a film forming sequence according to a fourth embodiment of the present disclosure.

FIG. 8 is a diagram illustrating a time chart of a film forming sequence according to a fifth embodiment of the present disclosure.

FIG. 9 is a diagram illustrating a time chart of a film forming sequence according to a sixth embodiment of the present disclosure.

FIG. 10 is a diagram illustrating a time chart of a film forming sequence according to a seventh embodiment of the present disclosure.

FIG. 11 is a diagram illustrating a time chart of a film forming sequence according to an eighth embodiment of the present disclosure.

FIG. 12 is a diagram illustrating a time chart of a film forming sequence according to a ninth embodiment of the present disclosure.

FIG. 13 is a diagram illustrating a time chart of a film forming sequence according to a tenth embodiment of the present disclosure.

FIG. 14 is a diagram illustrating data according to an embodiment of the present disclosure.

FIG. 15 is a diagram illustrating data according to a comparative example of the present disclosure.

FIG. 16 is a schematic view illustrating a configuration of a processing furnace of a substrate processing apparatus used in another embodiment of the present disclosure, in which the processing furnace portion is illustrated as a longitudinal sectional view.

FIG. 17 is a schematic view illustrating a configuration of a processing furnace of a substrate processing apparatus used in another embodiment of the present disclosure, in which the processing furnace portion is illustrated as a longitudinal sectional view.

### DETAILED DESCRIPTION

Hereinafter, a first embodiment of the present disclosure will be described.

### First Embodiment of the Present Disclosure

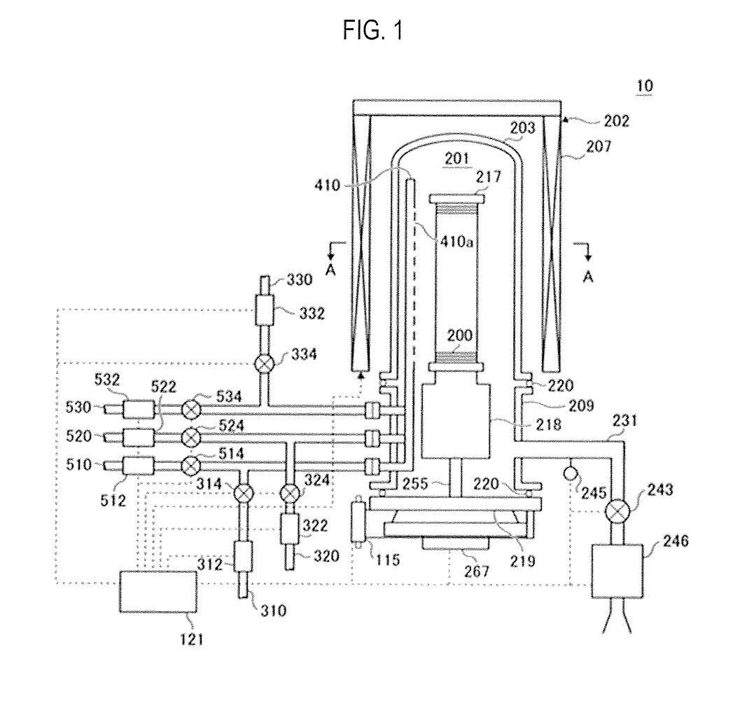

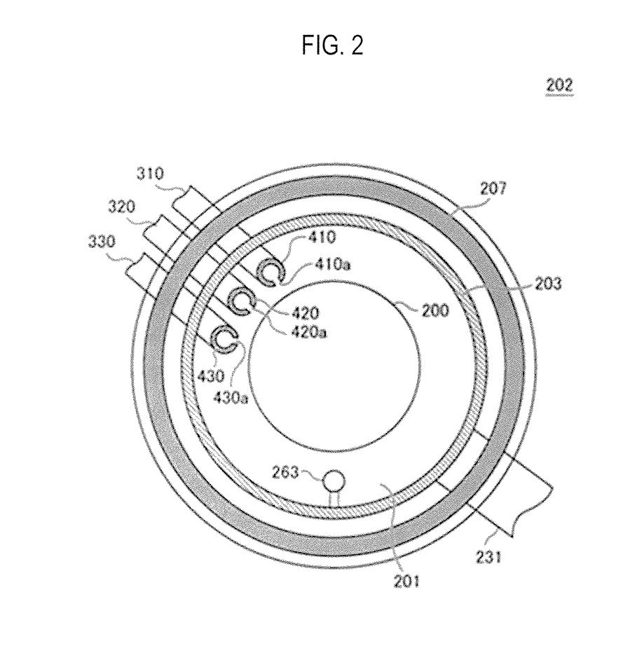

Hereinafter, a first embodiment of the present disclosure will be described with reference to FIGS. 1 and 2. A substrate processing apparatus 10 is configured as one example of an apparatus used in a substrate processing process which is one of processes of manufacturing a semiconductor device.

### (1) Configuration of Processing Furnace

A heater 207 serving as a heating means (a heating mechanism or a heating system) is installed in a processing furnace 202. The heater 207 has a cylindrical shape with a closed top thereof.

A reaction tube 203 that forms a reaction vessel (process vessel) in a concentric shape with the heater 207 is disposed inside the heater 207. The reaction tube 203 is formed of a heat resistant material or the like (e.g., quartz (SiO₂) or silicon carbide (SiC)), and has a cylindrical shape with a closed top and an open bottom.

A manifold 209 formed of a metal material such as stainless steel is installed below the reaction tube 203. The manifold 209 has a cylindrical shape, and a lower end opening thereof is airtightly occluded by a seal cap 219 serving as a lid formed of a metal material such as stainless steel. An O-ring 220 serving as a seal member is installed between the reaction tube 203 and the manifold 209, and between the manifold 209 and the seal cap 219. The process vessel is mainly configured by the reaction tube 203, the manifold 209 and the seal cap 219, and a process chamber 201 is formed within the process vessel. The process chamber 201 is configured to accommodate wafers 200 as substrates in a state where the wafers 200 are horizontally arranged in a vertical direction and in a multi-stage manner in a boat 217, which will be described later.

A rotation mechanism 267 configured to rotate the boat 217, which will be described later, is installed at a side of the seal cap 219 opposite to the process chamber 201. A rotation shaft 255 of the rotation mechanism 267 extends through the seal cap 219 and is connected to the boat 217. The rotation mechanism 267 is configured to rotate the wafers 200 by rotating the boat 217. The seal cap 219 is configured to be vertically moved by a boat elevator 115, which is an elevation mechanism vertically disposed at the outside of the reaction tube 203. The boat elevator 115 is configured to load and unload the boat 217 into and from the process chamber 201 by elevating or lowering the seal cap 219. That is, the boat elevator 115 is configured as a transfer device (transfer mechanism) that transfers the boat 217, i.e., the wafers 200, into and out of the process chamber 201.

The boat 217, which is used as a substrate support, is configured to support a plurality of wafers 200, e.g., 25 to 200 sheets, in a manner such that the wafers 200 are horizontally stacked in a vertical direction and multiple stages, i.e., being separated from each other, with the centers of the wafers 200 aligned with each other. The boat 217 is made of a heat-resistant material or the like (e.g., quartz or silicon carbide (SiC)). A lower portion of the boat 217 is supported horizontally by heat insulating plates 218, which are formed of a heat resistant material or the like (e.g., quartz or SiC) and stacked in a multi-stage manner. This configuration prevents a heat transfer from the heater 207 to the seal cap 219. However, this embodiment is not limited thereto. Instead of installing the heat insulating plates 218 at the lower portion of the boat 217, for example, a heat insulating tube formed of a tubular member, which is formed of a heat resistant material such as quartz or SiC, may be installed. The heater 207 may heat the wafers 200 accommodated in the process chamber 201 to a predetermined temperature.

Nozzles 410, 420 and 430 are installed in the process chamber 201 to pass through a sidewall of the manifold 209. Gas supply pipes 310, 320, and 330 as gas supply lines are connected to the nozzles 410, 420 and 430, respectively. In this manner, the three nozzles 410, 420 and 430, and the three gas supply pipes 310, 320 and 330 are installed in the processing furnace 202, and configured to supply plural types of gases, here, three types of gases (process gases and a precursor gas), into the process chamber 210 via dedicated lines, respectively.

Mass flow controllers (MFCs) 312, 322, and 332, which are flow rate controllers (flow rate control parts), and valves 314, 324, and 334, which are opening/closing valves, are respectively installed in the gas supply pipes 310, 320, and 330 in this order from an upstream side. Nozzles 410, 420, and 430 are coupled (connected) to front end portions of the gas supply pipes 310, 320, and 330, respectively. The nozzles 410, 420, and 430 are configured as L-shaped long nozzles, and horizontal portions thereof are installed to pass through a sidewall of the manifold 209. Vertical portions of the nozzles 410, 420, and 430 are installed in an annular space formed between the inner wall of the reaction tube 203 and the wafers 200 to extend upward (upward in the stacking direction of the wafers 200) along an inner wall of the reaction tube 203 (that is, extend upward from one end portion of the wafer arrangement region to the other end portion thereof). That is, the nozzles 410, 420, and 430 are installed in a region horizontally surrounding the wafer arrangement region in which the wafers 200 are arranged, along the wafer arrangement region at a side of the wafer arrangement region.

Gas supply holes 410a, 420a and 430a are formed in side surfaces of the nozzles 410, 420, and 430, respectively, to supply (discharge) gases. The gas supply holes 410a, 420a, and 430a are opened toward the center of the reaction tube 203, respectively. The gas supply holes 410a, 420a, and 430a are plurally formed from a lower portion to an upper portion of the reaction tube 203, and each has the same opening area at the same opening pitch.

As described above, in the method of supplying a gas according to this embodiment, the gas is transferred via the nozzles 410, 420, and 430, which are disposed inside a vertically long space of an annular shape defined by the inner wall of the reaction tube 203 and the end portions of the plurality of stacked wafers 200, i.e., a cylindrical space. The gas is finally discharged into the inside of the reaction tube 203 in the vicinity of the wafers 200 through the opened gas supply holes 410a, 420a and 430a of the nozzles 410, 420 and 430, respectively. Thus, a main flow of the gas in the reaction tube 203 is formed in a direction parallel to surfaces of the wafers 200, i.e., the horizontal direction. With this configuration, the gas can be uniformly supplied to the respective wafers 200, so that an advantageous effect of forming a thin film with uniform thickness on each of the wafers 200 can be provided. Further, a gas flowing above the surfaces of the wafers 200, i.e., a gas remaining after the reaction (residual gas), flows toward an exhaust port, i.e., the exhaust pipe 231 described later. A flow direction of the residual gas is not limited to the vertical direction and may be appropriately specified depending on a position of the exhaust port.

Further, carrier gas supply pipes 510, 520, and 530 for supplying a carrier gas are connected to the gas supply pipes 310, 320, and 330, respectively. MFCs 512, 522 and 532, and valves 514, 524 and 534 are installed in the carrier gas supply pipes 510, 520, and 530, respectively.

As one example of the foregoing configuration, a precursor gas as a process gas is supplied from the gas supply pipe 310 into the process chamber 201 through the MFC 312, the valve 314 and the nozzle 410. As the precursor gas, for example, a titanium tetrachloride (TiCl₄), which is Ti-containing precursor containing titanium (Ti) of a metal element, is used. TiCl₄ is halide (halogen-based precursor) containing chloride, and Ti is classified as a transition metal element.

The reaction gas that reacts with a precursor gas as a process gas is supplied from the gas supply pipe 320 into the process chamber 201 through the MFC 322, the valve 324 and the nozzle 420. As the reaction gas, for example, ammonia (NH₃), which is a nitriding-reducing agent and an N-containing gas containing nitrogen (N), is used.

A process gas is supplied from the gas supply pipe 330 into the process chamber 201 through the MFC 332, the valve 334 and the nozzle 430. As the process gas, for example, pyridine (C₅H₅N), which is a process gas reacting with byproducts produced by reaction of a precursor gas and a reaction gas, is used.

An inert gas, for example, a nitrogen (N₂) gas, is supplied from the carrier gas supply pipes 510, 520 and 530 into the process chamber 201 through the MFCs 512, 522 and 532, the valves 514, 524 and 534, and the nozzles 410, 420 and 430, respectively.

Here, in the present disclosure, the precursor gas (process gas) refers to a precursor in a gaseous state, for example, a gas obtained by vaporizing or sublimating a precursor in a liquid state or a solid state at room temperature under normal pressure, a precursor in a gaseous state at room temperature under normal pressure, or the like. When the term “precursor” is used herein, it may refer to “a liquid precursor in a liquid state,” “a solid precursor in a solid state,” “a precursor gas in a gaseous state,” or any combination of them. Like TiCl₄ or the like, when a liquid precursor, which is in a liquid state at room temperature under normal pressure, is used or a solid precursor, which is in a solid state at room temperature under normal pressure, is used, the liquid precursor or the solid precursor is vaporized or sublimated by a system such as a vaporizer, a bubbler, or, a sublimator, and then supplied as the precursor gas (TiCl₄ gas, etc.).

When the above-mentioned process gas flows via the gas supply pipes 310, 320, and 330, a process gas supply system is mainly configured by the gas supply pipes 310, 320 and 330, the MFCs 312, 322 and 332, and the valves 314, 324 and 334. It may be considered that the nozzles 410, 420 and 430 are included in the process gas supply system. The process gas supply system may be simply called a gas supply system.

When the Ti-containing gas (a Ti source) as a process gas flows via the gas supply pipe 310, a Ti-containing gas supply system is mainly configured by the gas supply pipe 310, the MFC 312 and the valve 314. It may also be considered that the nozzle 410 is included in the Ti-containing gas supply system. The Ti-containing gas supply system may be called a Ti-containing precursor supply system or may be simply called a Ti precursor supply system. When a TiCl₄ gas flows via the gas supply pipe 310, the Ti-containing gas supply system may be called a TiCl₄ gas supply system. The TiCl₄ gas supply system may also be called a TiCl₄ supply system. Also, the Ti-containing gas supply system may be called a halogen-based precursor supply system.

When a nitriding-reducing agent as a process gas flows via the gas supply pipe 320, a nitriding-reducing agent supply system is mainly configured by the gas supply pipe 320, the MFC 322 and the valve 324. It may be considered that the nozzle 420 is included in the nitriding reducing agent supply system. When an N-containing gas (N source) as a nitriding-reducing agent flows, the nitriding-reducing agent supply system may also be called an N-containing gas supply system. When an NH₃ gas flows via the gas supply pipe 320, the N-containing gas supply system may be called an NH₃ gas supply system. The NH₃ gas supply system may also be called a NH₃ supply system.

When C₅H₅N (pyridine) as a process gas flows via the gas supply pipe 330, a C₅H₅N gas supply system is mainly configured by the gas supply pipe 330, the MFC 332 and the valve 334. It may be considered that the nozzle 430 is included in the C₅H₅N gas supply system.

In addition, a carrier gas supply system is mainly configured by the carrier gas supply pipes 510, 520 and 530, the MFCs 512, 522 and 532, and the valves 514, 524 and 534. When an inert gas as a carrier gas flows, the carrier gas supply system may also be called an inert gas supply system. Since the inert gas also acts as a purge gas, the inert gas supply system may also be called a purge gas supply system.

An exhaust pipe 231 for exhausting an internal atmosphere of the process chamber 201 is installed in the manifold 209. Like the nozzles 410, 420 and 430, the exhaust pipe 231 is installed to pass through a sidewall of the manifold 209. As illustrated in FIG. 2, the exhaust pipe 231 is installed at a position opposite to the nozzles 410, 420, and 430 with the wafers 200 interposed therebetween. With this configuration, a gas supplied from the gas supply holes 410a, 420a and 430a into the vicinity of the wafers 200 in the process chamber 201 flows in the horizontal direction, i.e., in a direction parallel to the surfaces of the wafers 200, flows downward, and then is exhausted through the exhaust pipe 231. A main flow of the gas in the process chamber 201 is caused in the horizontal direction as described above.

A pressures sensor 245 serving as a pressure detector (pressure detecting part) for detecting an internal pressure of the process chamber 201, an auto pressure controller (APC) valve 243 serving as a pressure controller (pressure control part) for controlling the internal pressure of the process chamber 201, and a vacuum pump 246 serving as a vacuum exhaust device are connected to the exhaust pipe 231 in this order from an upstream side. When operating the vacuum pump 246, the APC valve 243 may be open or closed to vacuum-exhaust the internal atmosphere of the process chamber 201 or stop the vacuum-exhausting, respectively, and the internal pressure of the process chamber 201 may be adjusted by adjusting a degree of the valve opening of the APC valve 243 based on pressure information detected by the pressure sensor 245. Since the APC valve 243 forms a portion of the exhaust flow path of the exhaust system, the APC valve 243 serves as a pressure adjusting part, and an exhaust flow path opening and closing part capable of closing and further sealing the exhaust flow path of the exhaust system, i.e., an exhaust valve. Further, a trap device for capturing reaction byproducts or an unreacted precursor gas in an exhaust gas or a harm-removing device for removing a corrosive component or a toxic component included in an exhaust gas may be connected to the exhaust pipe 231. The exhaust system, i.e., an exhaust line, is mainly configured by the exhaust pipe 231, the APC valve 243, and the pressure sensor 245. Also, it may be considered that the vacuum pump 246 is included in the exhaust system. In addition, it may also be considered that a trap device or a harm-removing device is included in the exhaust system.

A temperature sensor 263 serving as a temperature detector is installed in the reaction tube 203, and an amount of electric current to be applied to the heater 207 is adjusted based on temperature information detected by the temperature sensor 263, so that the interior of the process chamber 201 has a desired temperature distribution. The temperature sensor 263 is configured in an L shape, like the nozzles 410, 420, and 430, and is installed along the inner wall of the reaction tube 203.

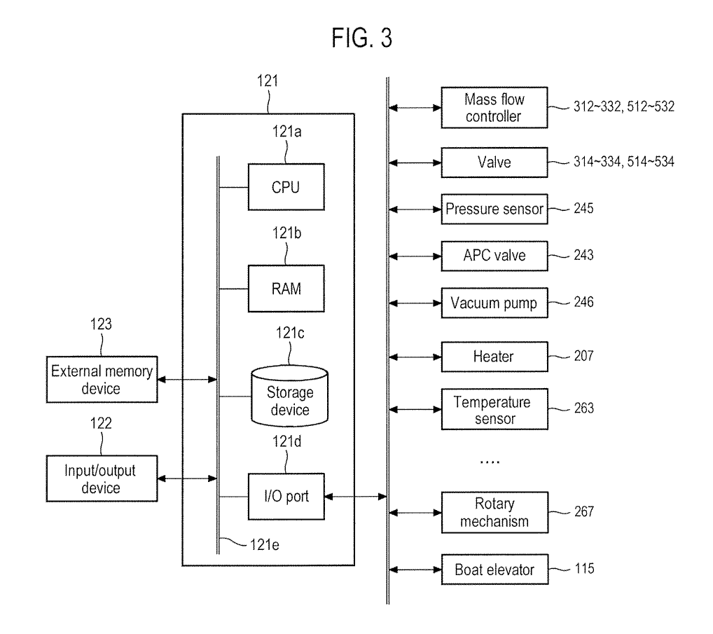

As illustrated in FIG. 3, a controller 121 serving as a control part (control means) is configured as a computer including a central processing unit (CPU) 121a, a random access memory (RAM) 121b, a memory device 121c, and an I/O port 121d. The RAM 121b, the memory device 121c, and the I/O port 121d are configured to exchange data with the CPU 121a via an internal bus 121e. An input/output device 122 configured as a touch panel or the like is connected to the controller 121.

The memory device 121c is configured with a flash memory, a hard disc drive (HDD), or the like. A control program for controlling operations of the substrate processing apparatus, a process recipe in which a sequence, condition, or the like for a substrate processing to be described later is written, and the like are readably stored in the memory device 121c. The process recipe, which is a combination of sequences, causes the controller 121 to execute each sequence in a substrate processing process to be described later in order to obtain a predetermined result, and functions as a program. Hereinafter, the process recipe, the control program, or the like may be generally referred to simply as a program. When the term “program” is used in the present disclosure, it should be understood as including the process recipe, the control program, or a combination of the process recipe and the control program. Further, the RAM 121b is configured as a memory area (work area) in which a program, data, or the like read by the CPU 121a is temporarily stored.

The I/O port 121d is connected to the above-described MFCs 312, 322, 332, 512, 522 and 532, the valves 314, 324, 334, 514, 524 and 534, the APC valve 243, the pressure sensor 245, the vacuum pump 246, the heater 207, the temperature sensor 263, the rotation mechanism 267, the boat elevator 115 and the like.

The CPU 121a is configured to read and execute the control program from the memory device 121c, and also to read the process recipe from the memory device 121c according to an operation command inputted from the input/output device 122, or the like. The CPU 121a is configured to control the flow rate adjusting operation of various types of gases by the MFCs 312, 322, 332, 512, 522, and 532, the opening/closing operation of the valves 314, 324, 334, 514, 524 and 534, the pressure adjusting operation based on an opening/closing operation of the APC valve 243 and the pressure sensor 245 by the APC valve 243, the temperature adjusting operation of the heater 207 based on the temperature sensor 263, the driving and stopping of the vacuum pump 246, the rotation and rotation speed adjusting operation of the boat 217 by the rotation mechanism 267, the elevation operation of the boat 217 by the boat elevator 115, and the like, according to the read process recipe.

The controller 121 is not limited to being configured as a dedicated computer and may be configured as a general-purpose computer. For example, the controller 121 of this embodiment may be configured by preparing an external memory device 123 storing the program as described above (e.g., a magnetic tape, a magnetic disc such as a flexible disc or a hard disc, an optical disc such as a compact disc (CD) or a digital versatile disc (DVD), a magneto-optical (MO) disc, a semiconductor memory such as a universal serial bus (USB) memory or a memory card, etc.), and installing the program on the general-purpose computer using the external memory device 123. A means for supplying a program to a computer, however, is not limited to the case of supplying the program through the external memory device 123. For example, the program may be supplied using a communication means such as the Internet or a dedicated line, rather than through the external memory device 123. The memory device 121c or the external memory device 123 is configured as a non-transitory computer-readable recording medium. Hereinafter, these means for supplying the program will also be generally referred to simply as “a recording medium.” When the term “recording medium” is used in the present disclosure, it may be understood as the memory device 121c, the external memory device 123, or both of the memory device 121c and the external memory device 123.

### (Substrate Processing Process)

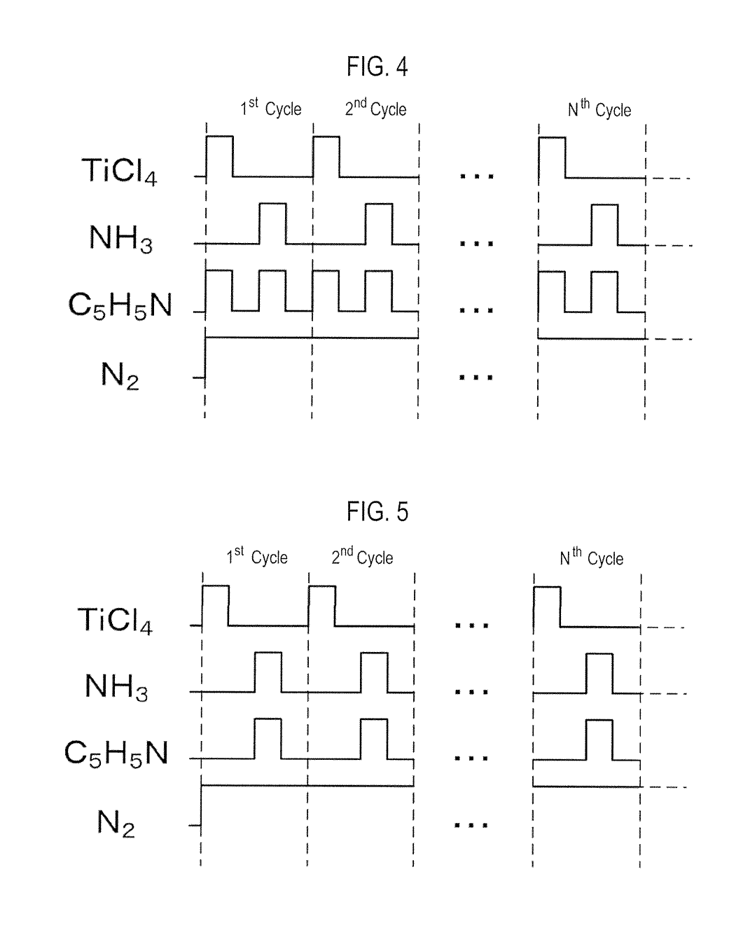

A first embodiment of a process of forming a metal film forming, for example, a gate electrode on a substrate, which is one of processes of manufacturing a semiconductor device, will be described with reference to FIG. 4. The process of forming a metal film is performed using the processing furnace 202 of the above-described substrate processing apparatus 10. In the following description, operations of respective parts constituting the substrate processing apparatus 10 are controlled by the controller 121.

In a film forming sequence (also simply referred to as a “sequence”) preferred in this embodiment, a process of supplying a first process gas (e.g., a TiCl₄ gas) containing a metal element (for example, Ti) to the wafers 200, a process of supplying a second process gas (for example, a NH₃ gas) as a nitriding-reducing agent including an element different from the first process gas to the wafers 200, and a process of supplying a third process gas (e.g., a C₅H₅N gas), which reacts with byproducts produced by the reaction between the first process gas and the second process gas, to the wafers 200 are performed by a predetermined number of times, thereby forming a metal nitride film (e.g., a TiN film) as a metal film on the wafers 200.

Specifically, like a sequence illustrated in FIG. 4, a cycle in which a process of supplying the TiCl₄ gas and the C₅H₅N gas and a process of supplying the NH₃ gas and the C₅H₅N gas are performed in a time-division manner is performed a predetermined number of times (n times) to thereby form a titanium nitride film (TiN film).

In the present disclosure, the expression “performing processing (also referred to as a process, a cycle, a step or the like) a predetermined number of times” means performing the processing or the like once or plural times. That is, it means performing the processing one or more times. FIG. 4 illustrates an example of repeating each processing (cycle) two cycles. The number of performing each processing or the like is appropriately selected depending on a film thicknesses required for a TiN film to be finally formed. That is, the number of performing each processing described above is determined according to a target film thickness.

Further, in the present disclosure, the term “time division” means a time-based separation. For example, in the present disclosure, performing the processes in the time division manner means performing the processes asynchronously, i.e., not synchronized with each other. In other words, it means performing the processes intermittently (in a pulse-wise manner) and/or alternately. That is, process gases supplied in each process are supplied without being mixed. When each process is performed a plurality of times, process gases supplied in each process are alternately supplied such that the gases are not mixed.

Also, when the term “wafer” is used in the present disclosure, it should be understood as either a “wafer per se,” or “the wafer and a laminated body (aggregate) of certain layers or films formed on a surface of the wafer”, that is, the wafer and certain layers or films formed on the surface of the wafer is collectively referred to as a wafer. Also, the term “surface of a wafer” is used in the present disclosure, it should be understood as either a “surface (exposed surface) of a wafer per se,” or a “surface of a certain layer or film formed on the wafer, i.e., an outermost surface of the wafer as a laminated body.”

Thus, in the present disclosure, the expression “a specified gas is supplied to a wafer” may mean that “the specified gas is directly supplied to a surface (exposed surface) of a wafer per se,” or that “the specified gas is supplied to a surface of a certain layer or film formed on the wafer, i.e., to an outermost surface of the wafer as a laminated body.” Also, in the present disclosure, the expression “a certain layer (or film) is formed on a wafer” may mean that “the certain layer (or film) is directly formed on the surface (exposed surface) of the wafer per se,” or that “the certain layer (or film) is formed on the surface of a certain layer or film formed on the wafer, i.e., on an outermost surface of the wafer as a laminated body.”

Also, in the present disclosure, the term “substrate” is interchangeably used with the term “wafer.” Thus, in the above description, the term “wafer” may be replaced with the term “substrate”.

Further, in the present disclosure, the term “metal film” refers to a film formed of a conductive material containing a metal element (which may also be simply called a conductive film), and the metal film includes a conductive metal nitride film, a conductive metal oxide film, a conductive metal oxynitride film, a conductive metal oxycarbide film, a conductive metal composite film, a conductive metal alloy film, a conductive metal silicide film, a conductive metal carbide film, a conductive metal carbonitride film, and the like. Also, the TiN film (titanium nitride film) is a conductive metal nitride film.

### (Wafer Charging and Boat Loading)

When a plurality of wafers 200 are charged on the boat 217 (wafer charging), as illustrated in FIG. 1, the boat 217 supporting the plurality of wafers 200 is lifted up by the boat elevator 115 to be loaded into the process chamber 201 (boat loading). In this state, the seal cap 219 seals the lower end opening of the manifold 209 via the O-ring 220.

### (Pressure Adjustment and Temperature Adjustment)

The interior of the process chamber 201 is vacuum-exhausted by the vacuum pump 246 to a desired pressure (degree of vacuum). At this time, the internal pressure of the process chamber 201 is measured by the pressure sensor 245, and the APC valve 243 is feedback-controlled based on the measured pressure information (pressure adjustment). The vacuum pump 246 is always kept in an operative state at least until the processing on the wafers 200 is completed. Further, the wafers 200 within the process chamber 201 are heated by the heater 207 to be a desired temperature. At this time, an amount of electric current supplied to the heater 207 is feedback-controlled based on the temperature information detected by the temperature sensor 263 so as to have a desired temperature distribution in the interior of the process chamber 201 (temperature adjustment). Further, the heating of the interior of the process chamber 201 by the heater 207 is continuously performed at least until the processing on the wafers 200 is completed. Subsequently, the rotation of the boat 217 and wafers 200 by the rotation mechanism 267 begins. Also, the rotation of the boat 217 and wafers 200 by the rotation mechanism 267 is continuously performed at least until the processing on the wafers 200 is completed.

### (TiN Film Forming Step)

Subsequently, a first embodiment of forming a TiN film will be described. A TiN film forming step includes a step of supplying a TiCl₄ gas and a C₅H₅N gas, a step of removing a residual gas, a step of supplying a NH₃ gas, a step of supplying a C₅H₅N gas, and a step of removing a residual gas, which will be described below.

### (Step of Supplying TiCl₄ Gas and C₅H₅N Gas)

The valve 314 is opened and the TiCl₄ gas is supplied into the gas supply pipe 310. A flow rate of the TiCl₄ gas flowing inside the gas supply pipe 310 is adjusted by the MFC 312, and then the TiCl₄ gas is supplied into the process chamber 201 from the gas supply hole 410a of the nozzle 410 and exhausted via the exhaust pipe 231. The valve 334 is simultaneously opened, and the C₅H₅N gas is supplied into the gas supply pipe 330. A flow rate of the C₅H₅N gas flowing inside the gas supply pipe 330 is adjusted by the MFC 332, and then the C₅H₅N gas is supplied into the process chamber 201 from the gas supply hole 430a of the nozzle 430 and exhausted via the exhaust pipe 231.

At this time, the TiCl₄ gas and the C₅H₅N gas are supplied to the wafers 200. That is, a surface of the wafers 200 is exposed to the TiCl₄ gas and the C₅H₅N gas. At this time, the valve 514 and the valve 534 are simultaneously opened, and an N₂ gas is supplied into the carrier gas supply pipes 510 and 530. A flow rate of the N₂ gas flowing inside the carrier gas supply pipes 510 and 530 is adjusted by the MFCs 512 and 532, and then the N₂ gas is supplied into the process chamber 201 together with the TiCl₄ gas and the C₅H₅N gas and exhausted via the exhaust pipe 231. At this time, in order to prevent the TiCl₄ gas and the C₅H₅N gas from flowing into the nozzle 420, the valve 524 is opened and the N₂ gas is supplied into the carrier gas supply pipe 520. The N₂ gas is supplied into the process chamber 201 through the gas supply pipe 320 and the nozzle 420 and exhausted via the exhaust pipe 231.

The APC valve 243 is appropriately adjusted to set the internal pressure of the process chamber 201 to be a pressure within a range of, for example, 1 to 3000 Pa, for example, 60 Pa. A supply flow rate of the TiCl₄ gas controlled by the MFC 312 is set to be within a range of, for example, 1 to 2000 sccm, for example, 100 sccm. A supply flow rate of the C₅H₅N gas controlled by the MFC 332 is set to be within a range of, for example, 1 to 4000 sccm, for example, 1000 sccm. A supply flow rate of the N₂ gas controlled by the MFCs 512, 522, and 532 is set to be within a range of, for example, 100 to 10000 sccm, for example, 1000 sccm. A time duration for which the TiCl₄ gas and the C₅H₅N gas are supplied to the wafers 200, i.e., a gas supply time (irradiation time) is set to be within a range of, for example, 0.1 to 30 seconds, for example, 10 seconds. At this time, the temperature of the heater 207 is set such that a temperature of the wafers 200 is to be within a range of, for example, room temperature to 450 degrees C., preferably, room temperature to 400 degrees C., for example, 350 degrees C. Gases flowing into the process chamber 201 are only the TiCl₄ gas, the C₅H₅N gas, and the N₂ gas, and a Ti-containing layer having a thickness of, for example, less than one atomic layer to several atomic layers, is formed on the outermost surface of the wafers 200 (a base film of the surface) according to the supply of the TiCl₄ gas. Further, in a case in which the TiCl₄ gas and the C₅H₅N gas are simultaneously supplied, it is particularly effective after a second cycle in which HCl or the like, which is byproducts produced as a NH₃ gas is supplied, remain within the process chamber.

It is preferred that the Ti-containing layer is a Ti layer, but a Ti(Cl) layer may be a main element of the Ti-containing layer. Also, the Ti layer includes a discontinuous layer, in addition to a continuous layer formed of Ti. That is, the Ti layer includes a Ti deposition layer having a thickness ranging from less than one atomic layer to several atomic layers formed of Ti. The Ti(Cl) layer is a Ti-containing layer that contains Cl, and may be a Ti layer containing Cl or an adsorption layer of TiCl₄.

The Ti layer containing Cl generally refers to all layers including, in addition to a continuous layer formed of Ti and containing Cl, a discontinuous layer and a Ti thin film containing Cl produced by overlapping the continuous layer and the discontinuous layer. A continuous layer formed of Ti and containing Cl may be referred to as a Ti thin film containing Cl. Ti constituting the Ti layer containing Cl includes, in addition to Ti whose bond with Cl is not been completely broken, Ti whose bond with Cl is completely broken.

The adsorption layer of TiCl₄ includes, in addition to a continuous absorption layer formed of TiCl₄ molecules, a discontinuous adsorption layer as well. That is, the adsorption layer of TiCl₄ includes an adsorption layer having a thickness of one molecular layer or less, which is formed of TiCl₄ molecules. The TiCl₄ molecules constituting the adsorption layer of TiCl₄ includes a molecule in which a bond of Ti and Cl is partially broken. That is, the adsorption layer of TiCl₄ may be a physical adsorption layer of TiCl₄ or a chemical adsorption layer of TiCl₄, or may include both of them.

Here, a layer having a thickness smaller than one atomic layer refers to an a discontinuously formed atomic layer, and a layer having a thickness equal to one atomic layer means a continuously formed atomic layer. Also, a layer having a thickness smaller than one molecular layer refers to a discontinuously formed molecular layer which is, and a layer having a thickness equal to one molecular layer refers to a continuously formed molecular layer. Further, the Ti(Cl) layer may include both the Cl-containing Ti layer and the adsorption layer of TiCl₄. However, as described above, the Ti(Cl) layer will be represented by the expression of “one atomic layer”, “several atomic layers”, or the like. This is also the same in the following example.

### (Residual Gas Removing Step)

After the Ti-containing layer is formed, the valves 314 and 334 are closed to stop the supply of the TiCl₄ gas and the C₅H₅N gas. At this time, while the APC valve 243 is opened, the interior of the process chamber 201 is vacuum-exhausted by the vacuum pump 246 to thereby remove the TiCl₄ gas and C₅H₅N gas that do not react or have contributed to the formation of the Ti containing layer, thereby remaining in the process chamber 201. That is, the TiCl₄ gas and C₅H₅N gas that do not react or that have contributed to the formation of the Ti containing layer, thereby remaining in a space in which the wafers 200 with the Ti-containing layer formed thereon exist, are removed. At this time, the valves 514, 524 and 534 are open so that the supply of the N₂ gas into the process chamber 201 is maintained. The N₂ gas acts as a purge gas to thereby increase an effect of removing from the process chamber 201 the TiCl₄ gas and C₅H₅N gas that do not react or that have contributed to the formation of the Ti containing layer, thereby remaining in the process chamber 201.

At this time, the gas remaining in the process chamber 201 may not completely be removed, and the interior of the process chamber 201 may not completely be purged. As the amount of the gas remaining in the process chamber 201 is very small, it may not adversely affect the subsequent step. A flow rate of the N₂ gas supplied into the process chamber 201 need not be high. For example, the approximately same amount of the N₂ gas as the volume of the reaction tube 203 (the process chamber 201) may be supplied, so that the purging process can be performed without adversely affecting the subsequent step. As described above, since the interior of the process chamber 201 is not completely purged, the purge time can be reduced which can improve the throughput. In addition, the consumption of the N₂ gas can also be restricted to a required minimal amount.

### (Step of Supplying NH₃ Gas and C₅H₅N Gas)

After the residual gas within the process chamber 201 is removed, the valve 324 is opened and the NH₃ gas is supplied into the gas supply pipe 320. A flow rate of the NH₃ gas flowing inside the gas supply pipe 320 is adjusted by the MFC 322, and then the NH₃ gas is supplied into the process chamber 201 from the gas supply hole 420a of the nozzle 420 and exhausted via the exhaust pipe 231. At this time, the NH₃ gas is supplied to the wafers 200. At this time, the valve 334 is simultaneously opened and the C₅H₅N gas is supplied into the gas supply pipe 330. The C₅H₅N gas flowing inside the gas supply pipe 330 is adjusted in a flow rate by the MFC 332 and then the C₅H₅N gas is supplied into the process chamber 201 from the gas supply hole 430a of the nozzle 430 and exhausted via the exhaust pipe 231. At this time, the C₅H₅N gas is supplied to the wafers 200. That is, the surface of the wafers 200 is exposed to the NH₃ gas and the C₅H₅N gas. At this time, the valve 524 and the valve 534 are simultaneously opened and the N₂ gas is supplied into the carrier gas supply pipes 520 and 530. The N₂ gas flowing inside the carrier gas supply pipes 520 and 530 is adjusted in a flow rate by the MFCs 522 and 532, and then the N₂ gas is supplied into the process chamber 201 together with the NH₃ gas and the C₅H₅N gas and exhausted via the exhaust pipe 231. At this time, in order to prevent the NH₃ gas and the C₅H₅N gas from flowing into the nozzle 410, the valve 514 is opened and the N₂ gas is supplied into the carrier gas supply pipe 510. The N₂ gas is supplied into the process chamber 201 through the gas supply pipe 310 and the nozzle 410 and exhausted via the exhaust pipe 231.

When the NH₃ gas is supplied, the APC valve 243 is appropriately adjusted to set an internal pressure of the process chamber 201 to be a pressure within a range of, for example, 1 to 3000 Pa, for example, to 60 Pa. A supply flow rate of the NH₃ gas controlled by the MFC 322 is set to be within a range of, for example, 1 to 20000 sccm, for example, 10000 sccm. A supply flow rate of the N₂ gas controlled by the MFCs 512, 522, and 532 is set to be within a range of, for example, 100 to 10000 sccm, for example, 1000 sccm. A time duration for which the NH₃ gas and the C₅H₅N gas are supplied to the wafers 200, i.e., a gas supply time (irradiation time), is set to be within a range of, for example, 0.1 to 60 seconds, for example, 30 seconds. The temperature of the heater 207 at this time is set to be substantially the same as that in the TiCl₄ gas and C₅H₅N gas supply step.

At this time, gases flowing into the process chamber 201 are only the NH₃ gas, the C₅H₅N gas and the N₂ gas. The NH₃ gas performs a substitution reaction with at least a portion of the Ti-containing layer formed on the wafers 200 in the TiCl₄ gas supply step. During the substitution reaction, Ti contained in the Ti-containing layer and N contained in the NH₃ gas are combined so that N is adsorbed onto the Ti-containing layer, and most of chlorine (Cl) contained in the Ti-containing layer is combined with hydrogen (H) contained in the NH₃ gas to thereby be extracted or eliminated from the Ti-containing layer and separated as reaction byproducts (also called as byproducts or impurities in some cases) such as HCl or NHₓCl as chloride from the Ti-containing layer. Accordingly, a layer including Ti and N (hereinafter, simply referred to as a TiN layer) is formed on the wafers 200. At this time, the separated byproducts such as HCl as chloride react with the C₅H₅N gas to form salt, so that it possible to discharge HCl in the form of salt.

### (Residual Gas Removing Step)

After the TiN layer is formed, the valve 324 and the valve 334 are closed to stop the supply of the NH₃ gas and the C₅H₅N gas. At this time, while the APC valve 243 is in an open state, the interior of the process chamber 201 is vacuum-exhausted by the vacuum pump 246 to remove from the process chamber 201 the NH₃ gas and byproducts formed of salt that do not react or that have contributed to the formation of the Ti containing layer, thereby remaining in the process chamber 201. That is, the NH₃ gas and C₅H₅N gas, or the byproducts that do not react or that have contributed to the formation of the TiN layer, thereby remaining in the space in which the wafers 200 with the TiN layer formed thereon exist, are removed. At this time, the valves 514, 524 and 534 are opened so that the supply of the N₂ gas into the process chamber 201 is maintained. The N₂ gas acts as a purge gas to thereby increase an effect of removing from the process chamber 201 the NH₃ gas and C₅H₅N gas or byproducts that do not react or that have contributed to the formation of the TiN layer, thereby remaining in the process chamber 201.

At this time, like the residual gas removing step after the TiCl₄ gas supply step, the gas remaining in the process chamber 201 may not be completely removed and the interior of the process chamber 201 may not be completely purged.

### (Performing Predetermined Number of Times)

A cycle in which the TiCl₄ gas and C₅H₅N gas supply step, the residual gas removing step, the NH₃ gas and C₅H₅N gas supply step, and the residual gas removing step described above are sequentially performed in a time-division manner is performed one or more times (predetermined number of times), that is, the process of the TiCl₄ gas and C₅H₅N gas supply step, the residual gas removing step, the NH₃ gas and C₅H₅N gas supply step, and the residual gas removing step is set to one cycle, and the process is executed by n cycles (where n is an integer equal to or greater than 1) to form a TiN film having a predetermined thickness (for example, 0.1 to 10 nm) on the wafers 200. Preferably, the foregoing cycle is repeatedly performed a plurality of times.

### (Purging and Returning to Atmospheric Pressure)

After the TiN film having a predetermined thickness is formed, the valves 514, 524, and 534 are opened to supply the N₂ gas from the carrier gas supply pipes 510, 520, and 530, respectively, into the process chamber 201 and the N₂ gas is exhausted through the exhaust pipe 231. The N₂ gas acts as a purge gas, and thus, the interior of the process chamber 201 is purged with the inert gas so that the gas or the byproducts remaining in the process chamber 201 are removed from the process chamber 201 (i.e., purging). Thereafter, an atmosphere in the process chamber 201 is substituted with the inert gas (i.e., inert gas substitution), and the internal pressure of the process chamber 201 returns to normal pressure (i.e., returning to atmospheric pressure).

### (Boat Unloading and Wafer Discharging)

The seal cap 219 descends by the boat elevator 115 to open the lower end of the manifold 209. Then, the processed wafers 200 are unloaded to the outside of the process chamber 201 through the lower end of the manifold 209, with being supported by the boat 217 (boat unloading). The processed wafers 200 are discharged from the boat 217 (wafer discharging).

### (3) Effects of the Embodiment

According to this embodiment, one or more effects are provided as described below.

In this embodiment, in a state where the substrate is maintained at a temperature of room temperature or more and 450 degrees C. or less, a cycle of simultaneous supplying TiCl₄ and C₅H₅N→removing a residual gas→simultaneous supplying NH₃ and C₅H₅N→removing a residual gas is set as one cycle. The cycle is repeatedly performed to form a TiN film, and byproducts including HCl as chloride separated at that time are discharged in form of salt.

Thus, (1) A factor of hindering adsorption of a process gas (TiCl₄ or NH₃) onto the surface of the substrate, which is caused by the reattachment of HCl or NHₓCl that is a reaction by-product onto the substrate, can be reduced;

(2) When NH₃ is supplied, a reaction between HCl that is the reaction by-product and NH₃ is suppressed, and thus, the supplied NH₃ can be effectively used in the film forming process. In addition, when TiCl₄ is supplied, it is particularly effective after the second cycle in which reaction byproducts are produced;

(3) Since the residual Cl can be reduced, an increase in resistivity due to Cl can be suppressed; and

(4) Since the factor of hindering absorption of the process gas is removed, a film formation rate can increase.

### Second Embodiment of the Present Disclosure

In the first embodiment, the example of forming a TiN film by simultaneously supplying the TiCl₄ gas and the C₅H₅N gas, and simultaneously supplying the NH₃ gas and the C₅H₅N gas. In this embodiment, the example of forming the TiN film by supplying the TiCl₄ gas and simultaneously supplying the NH₃ gas and the C₅H₅N gas will be described with reference to FIG. 5. Detailed descriptions of the same parts as those of the first embodiment will be omitted and only parts different from those of the first embodiment will be described hereinafter.

In an preferred sequence of the this embodiment, a cycle in which, for example, the TiCl₄ gas as a first process gas is supplied to the wafers 200, and then, for example, the NH₃ gas as a second process gas and, for example, the C₅H₅N gas as a third process gas that reacts with byproducts produced by the reaction of the first process gas and the second process gas are simultaneously supplied is performed a predetermined number of times (n times) to form a TiN film as a metal film on the wafer.

This embodiment is different from the first embodiment in that, in the TiN film forming step, a cycle of a TiCl₄ gas supply step, a residual gas removing step, a NH₃ gas and C₅H₅N gas supply step, and a residual gas removing step is sequentially performed n times (where n is an integer equal to or greater than 1) in a time-division manner, but the process sequence and process conditions of each step are substantially the same as those of the first embodiment.

In this embodiment, in a state where the substrate is maintained at a temperature of room temperature or more and 450 degrees C. or less, a cycle of supplying TiCl₄→removing residual gas→simultaneously supplying NH₃ and C₅H₅N→removing residual gas is set to one cycle and the cycle is repeatedly performed to form the TiN film, and byproducts such as HCl as chloride separated at that time are discharged as salt.

Thus, (1) A factor of hindering adsorption of a process gas (TiCl₄ or NH₃) onto the surface of the substrate, which is caused by the reattachment of HCl or NHₓCl that is the reaction by-product onto the substrate, can be reduced;

(2) When NH₃ is supplied, a reaction between HCl that is the reaction byproduct and NH₃ is suppressed, and thus, the supplied NH₃ can be effectively used in the film forming process;

(3) Since the residual Cl can be reduced, an increase in resistivity due to Cl can be suppressed; and

(4) Since the factor of hindering absorption of the process gas is removed, a film formation rate can increase.

### Third Embodiment of the Present Disclosure

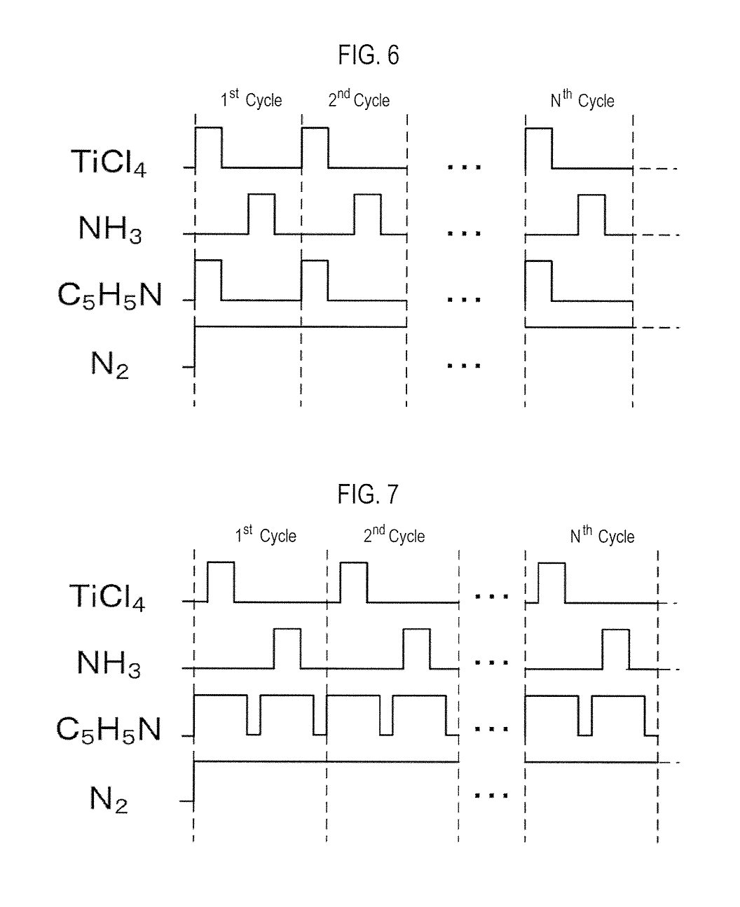

In this embodiment, an example of forming a TiN film by simultaneously supplying the TiCl₄ gas and the C₅H₅N gas and supplying the NH₃ gas will be described with reference to FIG. 6. Detailed descriptions of the same parts as those of the first embodiment will be omitted and only parts different from those of the first embodiment will be described hereinafter.

In a preferred sequence of the this embodiment, a cycle in which, for example, the TiCl₄ gas as a first process gas and, for example, the C₅H₅N gas as a third process gas that reacts with byproducts produced by the reaction of the first process gas and a second process gas are simultaneously supplied to the wafers 200, and then, for example, the NH₃ gas as the second process gas is supplied is performed a predetermined number of times (n times) to form the TiN film as a metal film on the wafer.

This embodiment is different from the first embodiment in that, in the TiN film forming step, a cycle of a TiCl₄ gas and C₅H₅N gas supply step, a residual gas removing step, the NH₃ gas supply step and a residual gas removing step is sequentially performed n times (where n is an integer equal to or greater than 1) in a time-division manner, but the process sequence and process conditions of each step are substantially the same as those of the first embodiment.

In this embodiment, in a state where the substrate is maintained at a temperature of room temperature or more and 450 degrees C. or less, a cycle of simultaneously supplying TiCl₄ and C₅H₅N gases→removing residual gas→supplying NH₃→removing residual gas is set to one cycle, and the cycle is repeatedly performed to form in the TiN film, and byproducts such as HCl as chloride separated at that time are discharged as salt.

Thus, (1) A factor of hindering adsorption of a process gas (TiCl₄ or NH₃) onto the surface of the substrate, which is caused by the reattachment of HCl or NHₓCl that is the reaction by-product onto the substrate, can be reduced;

(2) When TiCl₄ is supplied, it is particularly effective after the second cycle in which reaction byproducts are produced;

(3) Since the residual Cl can be reduced, an increase in resistivity due to Cl can be suppressed; and

(4) Since the factor of hindering absorption of the process gas is removed, a film formation rate can increase.

### Fourth Embodiment of the Present Disclosure

In this embodiment, an example of forming a TiN film by simultaneously supplying the TiCl₄ gas and the C₅H₅N gas, and simultaneously supplying the NH₃ gas and the C₅H₅N gas will be described in more detail with reference to FIG. 7. Detailed descriptions of the same parts as those of the first embodiment will be omitted and only parts different from those of the first embodiment will be described hereinafter.

In a preferred sequence of the this embodiment, a cycle in which supply of the C₅H₅N gas, for example, as a third process gas that reacts with byproducts produced by reaction of a first process gas and a second process gas starts, and supply of the TiCl₄ gas, for example, as a first process gas starts and stops before stopping the supply of the C₅H₅N gas, supply of the C₅H₅N gas as the third process gas that reacts with byproducts produced by reaction of the first process gas and the second process gas starts, supply of the NH₃ gas as the second process gas starts and stops before stopping the supply of the C₅H₅N gas, with respect to the wafers 200, is performed a predetermined number of times (n times) to form the TiN film as a metal film on the wafer.

This embodiment is different from the first embodiment in that, in a TiN film forming step, when the cycle of the TiCl₄ gas and C₅H₅N gas supply step, the residual gas removing step, the NH₃ gas and C₅H₅N gas supply step, and the residual gas removing step is sequentially performed n times (where n is an integer equal to or greater than 1) in a time-division manner, a supply time of the C₅H₅N gas is set to be longer than those of the TiCl₄ gas and the NH₃ gas, but the process sequence and process conditions of each step are substantially the same as those of the first embodiment.

According to this embodiment, the following effects are provided.

(1) A factor of hindering adsorption of a process gas (TiCl₄ or NH₃) onto the surface of the substrate, which is caused by the reattachment of HCl or NHₓCl that is the reaction by-product onto the substrate, can be reduced.

(2) When NH₃ is supplied, a reaction between HCl that is the reaction by-product and NH₃ is suppressed, and thus, the supplied NH₃ can be effectively used in the film forming process. In addition, when TiCl₄ is supplied, it is particularly effective after the second cycle in which reaction byproducts are produced.

(3) Since the residual Cl can be reduced, an increase in resistivity due to Cl can be suppressed.

(4) Since the factor of hindering absorption of the process gas is removed, a film formation rate can increase.

### Fifth Embodiment of the Present Disclosure

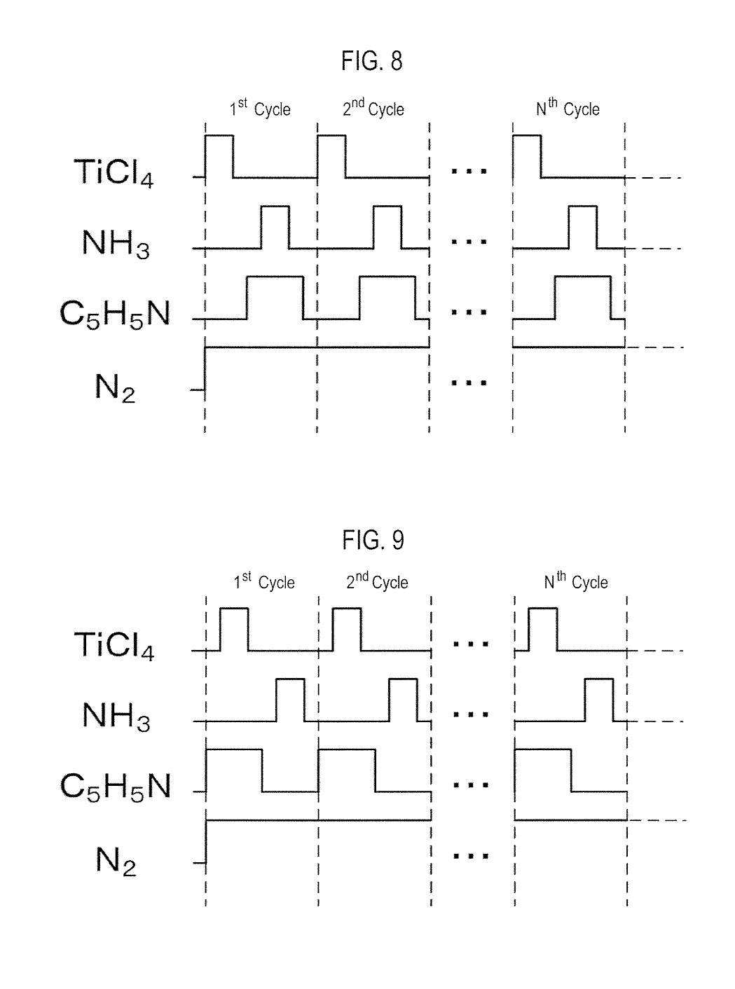

In this embodiment, an example of forming a TiN film by supplying the TiCl₄ gas and simultaneously supplying the NH₃ gas and the C₅H₅N gas will be described in more detail with reference to FIG. 8. Detailed descriptions of the same parts as those of the first embodiment will be omitted and only parts different from those of the first embodiment will be described hereinafter.

In a preferred sequence of the this embodiment, a cycle in which the supply of the TiCl₄ gas as a first process gas starts, the supply of the C₅H₅N gas, for example, as a third process gas that reacts with byproducts produced by reaction of the first process gas and a second process gas starts, the supply of the NH₃ gas, for example, as the second process gas starts and stops before stopping the supply of the C₅H₅N gas, with respect to the wafers 200, is performed a predetermined number of times (n times) to form the TiN film as a metal film on the wafer.

This embodiment is different from the first embodiment in that, in the TiN film forming step, in a state where the substrate is maintained at a temperature of room temperature or more and 450 degrees C. or less, when the cycle of the TiCl₄ gas supply step, the residual gas removing step, the NH₃ gas and C₅H₅N gas supply step, and the residual gas removing step is sequentially performed n times (where n is an integer equal to or greater than 1) in a time-division manner, a supply time of the C₅H₅N gas is set to be longer than that of the NH₃ gas, but the process sequence and process conditions of each step are substantially the same as those of the first embodiment.

According to this embodiment, the following effects are provided.

(1) A factor of hindering adsorption of a process gas (TiCl₄ or NH₃) onto the surface of the substrate, which is caused by the reattachment of HCl or NHₓCl that is the reaction by-product onto the substrate, can be reduced.

(2) When NH₃ is supplied, a reaction between HCl that is the reaction byproduct and NH₃ is suppressed, and thus, the supplied NH₃ can be effectively used in the film forming process.

(3) Since the residual Cl can be reduced, an increase in resistivity due to Cl can be suppressed.

(4) Since the factor of hindering absorption of the process gas is removed, a film formation rate can increase.

### Sixth Embodiment of the Present Disclosure

In this embodiment, an example of forming a TiN film by simultaneously supplying the TiCl₄ gas and the C₅H₅N gas and supplying the NH₃ gas will be described in more detail with reference to FIG. 9. Detailed descriptions of the same parts as those of the first embodiment will be omitted and only parts different from those of the first embodiment will be described hereinafter.

In preferred sequence of the this embodiment, a cycle in which the supply of the C₅H₅N gas, for example, as a third process gas that reacts with byproducts produced by reaction of a first process gas and a second process gas starts, the supply of the TiCl₄ gas, for example, as the first process gas starts and stops before stopping the supply of the C₅H₅N gas, and the NH₃ gas, for example, as the second process gas is supplied, with respect to the wafers 200, is performed a predetermined number of times (n times) to form the TiN film as a metal film on the wafer.

This embodiment is different from the first embodiment in that, in the TiN film forming step, when the cycle of the TiCl₄ gas and C₅H₅N gas supply step, the residual gas removing step, the NH₃ gas supply step, and the residual gas removing step is sequentially performed n times (where n is an integer equal to or greater than 1) in a time-division manner, a supply time of the C₅H₅N gas is set to be longer than that of the TiCl₄ gas, but the process sequence and process conditions of each step are substantially the same as those of the first embodiment.

According to this embodiment, the following effects are provided.

(1) A factor of hindering adsorption of a process gas (TiCl₄ or NH₃) onto the surface of the substrate, which is caused by the reattachment of HCl or NHₓCl that is the reaction by-product onto the substrate, can be reduced.

(2) When NH₃ is supplied, a reaction between HCl that is the reaction by-product and NH₃ is suppressed, and thus, the supplied NH₃ can be effectively used in the film forming process.

(3) Since the residual Cl can be reduced, an increase in resistivity due to Cl can be suppressed.

(4) Since the factor of hindering absorption of the process gas is removed, a film formation rate can increase.

### Seventh Embodiment of the Present Disclosure

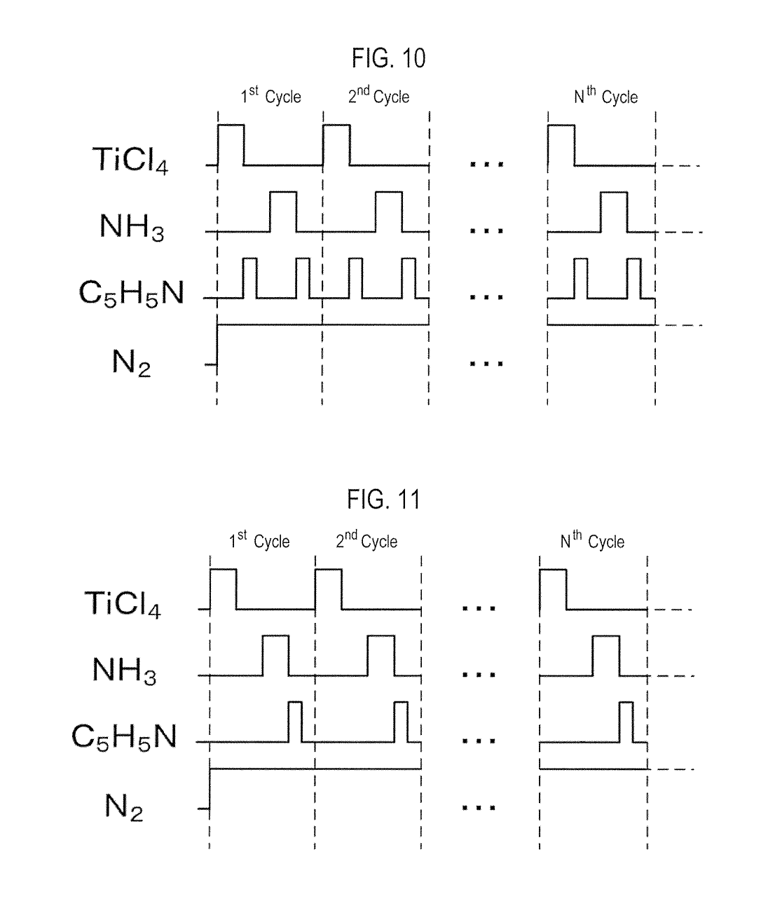

In this embodiment, an example of forming a TiN film by supplying the TiCl₄ gas, supplying the C₅H₅N gas, supplying the NH₃ gas, and supplying the C₅H₅N gas will be described in more detail with reference to FIG. 10. Detailed descriptions of the same parts as those of the first embodiment will be omitted and only parts different from those of the first embodiment will be described hereinafter.

In preferred sequence of the this embodiment, a cycle in which the TiCl₄ gas, for example, as a first process gas is supplied, the C₅H₅N gas, for example, as a third process gas that reacts with byproducts produced by reaction of the first process gas and a second process gas is supplied, the NH₃ gas, for example, as the second process gas is supplied, and the C₅H₅N gas is supplied, with respect to the wafers 200, is performed a predetermined number of times (n times) to form the TiN film as a metal film on the wafer.

This embodiment is different from the first embodiment in that, in the TiN film forming step, the cycle of the TiCl₄ gas supply step, the C₅H₅N gas supply step, the residual gas removing step, the NH₃ gas supply step, the C₅H₅N gas supply step, and the residual gas removing step is sequentially performed n times (where n is an integer equal to or greater than 1) in a time-division manner, but the process sequence and process conditions of each step are substantially the same as those of the first embodiment.

In this embodiment, in a state where the substrate is maintained at a temperature of room temperature or more and 450 degrees C. or less, the cycle of supplying TiCl₄ gas→supplying C₅H₅N gas→removing residual gas→supplying NH₃ gas→supplying C₅H₅N gas→removing residual gas is set to one cycle, and the cycle is repeatedly performed to form the TiN film and byproducts such as HCl as chloride separated at that time are discharged as salt.

Thus, (1) Since HCl attached to a site to which TiCl₄ or NH₃ is adsorbed is removed, a film formation rate can increase; and

(2) Since the residual Cl can be reduced, an increase in resistivity due to Cl can be suppressed.

### Eighth Embodiment of the Present Disclosure

In this embodiment, an example of forming a TiN film by supplying the TiCl₄ gas, supplying the NH₃ gas, and supplying the C₅H₅N gas will be described in more detail with reference to FIG. 11. Detailed descriptions of the same parts as those of the first embodiment will be omitted and only parts different from those of the first embodiment will be described hereinafter.

In a preferred sequence of the this embodiment, a cycle in which the TiCl₄ gas, for example, as a first process gas is supplied, the NH₃ gas, for example, as a second process gas is supplied, and the C₅H₅N gas, for example, as a third process gas that reacts with byproducts produced by reaction of the first process gas and the second process gas is supplied, with respect to the wafers 200, is performed a predetermined number of times (n times) to form the TiN film as a metal film on the wafer.

This embodiment is different from the first embodiment in that, in the TiN film forming step, the cycle of the TiCl₄ gas supply step, the residual gas removing step, the NH₃ gas supply step, the C₅H₅N gas supply step, and the residual gas removing step is sequentially performed n times (where n is an integer equal to or greater than 1) in a time-division manner, but the process sequence and process conditions of each step are substantially the same as those of the first embodiment.

In this embodiment, in a state where the substrate is maintained at a temperature of room temperature or more and 450 degrees C. or less, a cycle of supplying TiCl₄ gas→removing residual gas→supplying NH₃ gas→supplying C₅H₅N gas→removing residual gas is set to one cycle and the cycle is repeatedly performed to form the TiN film and the byproducts such as HCl as chloride separated at that time are discharged as salt.

Thus, (1) Since HCl attached to a site to which TiCl₄ or NH₃ is adsorbed is removed, a film formation rate can increase; and

(2) Since the residual Cl can be reduced, an increase in resistivity due to Cl can be suppressed.

### Ninth Embodiment of the Present Disclosure

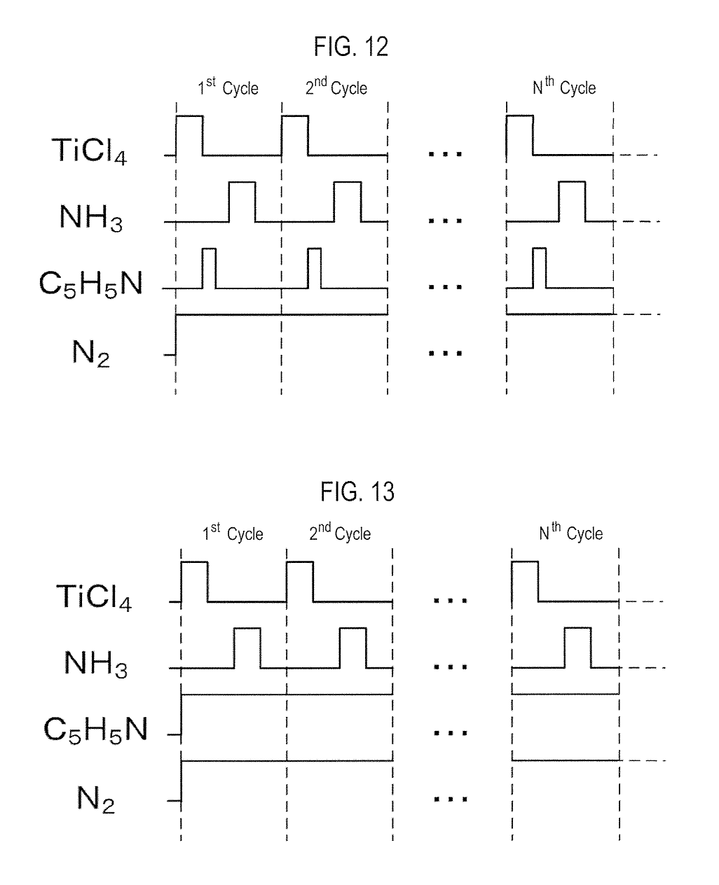

In this embodiment, an example of forming a TiN film by supplying the TiCl₄ gas, supplying the C₅H₅N gas, and supplying the NH₃ gas will be described in more detail with reference to FIG. 12. Detailed descriptions of the same parts as those of the first embodiment will be omitted and only parts different from those of the first embodiment will be described hereinafter.

In a preferred sequence of the this embodiment, a cycle in which the TiCl₄ gas, for example, as a first process gas is supplied, the C₅H₅N gas, for example, as a third process gas that reacts with byproducts produced by reaction of the first process gas and a second process gas is supplied, and the NH₃ gas, for example, as the second process gas is supplied, with respect to the wafers 200, is performed a predetermined number of times (n times) to form a TiN film as a metal film on the wafer.

This embodiment is different from the first embodiment in that, in the TiN film forming step, the cycle of the TiCl₄ gas supply step, the C₅H₅N gas supply step, the residual gas removing step, the NH₃ gas supply step, and the residual gas removing step is sequentially performed n times (where n is an integer equal to or greater than 1) in a time-division manner, but the process sequence and process conditions of each step are substantially the same as those of the first embodiment.

In this embodiment, in a state where the substrate is maintained at a temperature of room temperature or more and 450 degrees C. or less, a cycle of supplying TiCl₄ gas→supplying C₅H₅N gas→removing residual gas→supplying NH₃ gas→removing residual gas is set to one cycle and the cycle is repeatedly performed to form the TiN film and byproducts such as HCl as chloride separated at that time are discharged as salt.

Thus, (1) A factor of hindering adsorption of a process gas (TiCl₄ or NH₃) onto the surface of the substrate, which is caused by the reattachment of HCl or NHₓCl that is the reaction byproduct onto the substrate, can be reduced;

(2) Since the residual Cl can be reduced, an increase in resistivity due to Cl can be suppressed; and

(3) Since the factor of hindering absorption of the process gas is removed, a film formation rate can increase.

### Tenth Embodiment of the Present Disclosure

In this embodiment, an example of forming a TiN film by supplying the C₅H₅N gas, supplying the TiCl₄ gas, and supplying the NH₃ gas will be described in more detail with reference to FIG. 13. Detailed descriptions of the same parts as those of the first embodiment will be omitted and only parts different from those of the first embodiment will be described hereinafter.

In a preferred sequence of the this embodiment, a cycle in which the C₅H₅N gas, for example, as a third process gas that reacts with byproducts produced by reaction of a first process gas and a second process gas is continuously supplied, the TiCl₄ gas, for example, as the first process gas is supplied during the supple of the third process gas, and the NH₃ gas, for example, as the second process gas is supplied, with respect to the wafers 200, is performed a predetermined number of times (n times) to form the TiN film as a metal film on the wafer.

This embodiment is different from the first embodiment in that, in the TiN film forming step, the C₅H₅N gas is continuously supplied while the cycle of the TiCl₄ gas supply step, the residual gas removing step, the NH₃ gas supply step, and the residual gas removing step is sequentially performed n times (where n is an integer equal to or greater than 1) in a time-division manner, but the process sequence and process conditions of each step are substantially the same as those of the first embodiment.

In this embodiment, in a state where the substrate is maintained at a temperature of room temperature or more and 450 degrees C. or less, a cycle of supplying a TiCl₄ gas→removing a residual gas→supplying a NH₃ gas→supplying a C₅H₅N gas→removing a residual gas is set to one cycle and the C₅H₅N gas is continuously supplied during the cycle is repeatedly performed a predetermined cycle to form the TiN film and byproducts such as HCl as chloride separated at that time are discharged as salt.

Thus, (1) A factor of hindering adsorption of a process gas (TiCl₄ or NH₃) to the surface of the substrate, which is caused by the reattachment of HCl or NHₓCl that is the reaction by-product onto the substrate, can be reduced;

(2) When NH₃ is supplied, a reaction between HCl that is the reaction byproduct and NH₃ is suppressed, and thus, the supplied NH₃ can be effectively used in the film forming process;

(3) Since the residual Cl can be reduced, an increase in resistivity due to Cl can be suppressed; and

(4) Since the factor of hindering absorption of the process gas is removed, a film formation rate can increase.

In the present disclosure, a timing for supplying the C₅H₅N (pyridine) gas may be any time before or after the supply of the TiCl₄ gas and the NH₃ gas, and any timing is effective when byproducts (for example, HCl) are produced. In particular, it is most effective when a NH₃ (ammonia) gas is supplied.

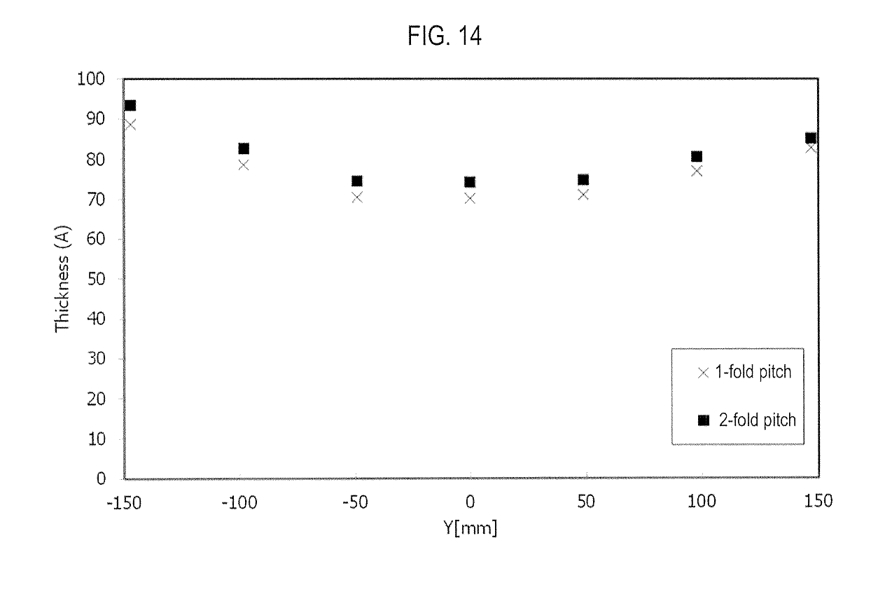

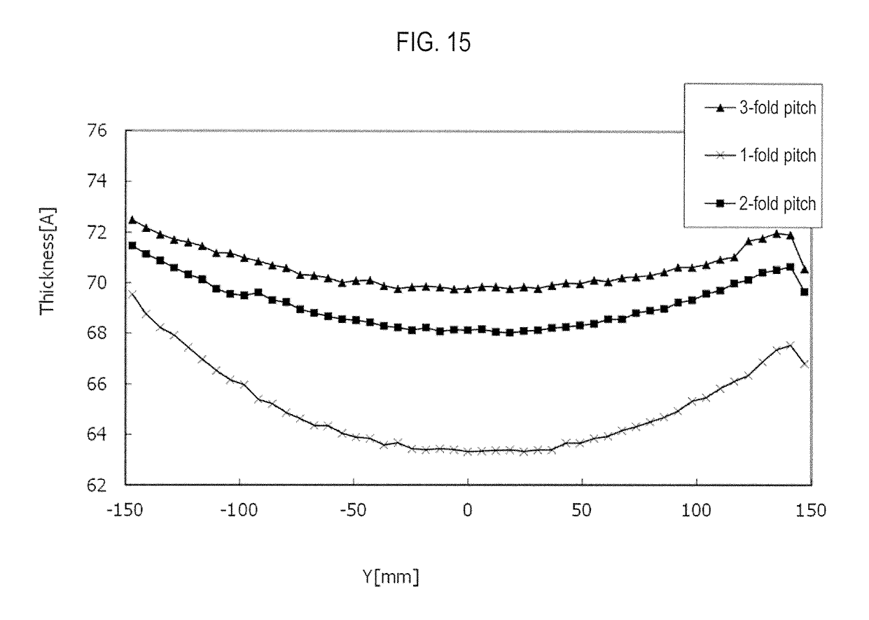

FIG. 14 shows data according to an embodiment of the present disclosure, and FIG. 15 shows data according to comparative examples. FIG. 14 illustrates data when a TiN film was formed at a temperature of 380 degrees C., and FIG. 15 illustrates data when an Si₃N₄ film was formed at a temperature of 630 degrees C. using a general method, and in FIGS. 14 and 15, the vertical axis represents a film thickness and the horizontal axis represents a distance from the center of a wafer.

In case of the TiN film of FIG. 14, data of 1-fold pitch and 2-fold pitch are compared, and in case of the Si₃N₄ film of FIG. 15, data of 1-fold pitch, 2-fold pitch, and 3-fold pitch are compared. Here, the 1-fold pitch refers to a case of introducing 100 sheets of wafers into a boat for 100 sheets, while the 2-fold pitch refers to a case of accommodating a total of 50 sheets of wafers by introducing the wafers into the boat at an interval of 1 sheet. That is, a space distance between the wafers is doubled from 1-fold pitch to 2-fold pitch.

When it is set from the 1-fold pitch to the 2-fold pitch, a flow rate of gas flowing in the central portion of a wafer increases, and it can be seen that variations in the film thickness distribution are small in the TiN film formation, while variations in the film thickness distribution is large in the Si₃N₄ film formation. When a high temperature film formation is performed like the Si₃N₄ film formation, NHₓCl or the like is produced as byproducts, and hindrance (a loading effect or the like) of film formation due to adsorption of NHₓCl or the like does not occur. Thus, it is considered that a film thickness distribution is determined only by the supply of a precursor gas. Meanwhile, as a factor causing occurrence of such a phenomenon in the TiN film formation, it may be considered that adhesion of the byproducts HCl, adhesion of NHₓCl resulting from a reaction between HCl and NH₃, or the like occurs in film formation (low temperature film formation, etc.) at an intermediate temperature or lower, for example, a temperature not more than 450 degrees C., like TiN. Thus, in the present disclosure, C₅H₅N (pyridine) is supplied to form salt with the byproducts HCl or the like and the pyridine in film formation at a temperature of 450 degrees C. or less, so that the reaction between HCl and NH₃ is suppressed. Further, in a film formation performed at a temperature more than 450 degrees C., hindrance (a loading effect or the like) of film formation due to adsorption of NHₓCl or the like does not occur, and thus, it is considered that the effect of supplying pyridine may not be obtained.

In the TiN film formation by alternately supplying TiCl₄ as a general chlorine gas and NH₃ as a nitriding reducing gas, the byproducts HCl are adsorbed onto the film surface, which hinder a film formation reaction, or react with the supplied NH₃ to thereby form an ammonium chloride, which acts as a factor of hindering film formation. In addition, such an influence causes decline in a film formation rate or degradation of film quality such as an increase in resistivity, or the like. However, according to the present disclosure, when HCl is generated during the film formation reaction, pyridine (C₅H₅N), which is a gas generating salt by reacting with HCl, for example, is simultaneously supplied, so that HCl can be discharged in the form of salt. Thus, a method capable of eliminating a factor of hindering film formation can be provided. As described above, the present disclosure is particularly effective for film formation performed at a temperature of 450 degrees C. or less. Further, since HCl and pyridine react to each other even at a room temperature, the present disclosure is effective for a process performed at room temperature or higher, which is a process temperature required for forming a TiN film.

### Other Embodiments

The present disclosure is not limited to the foregoing embodiments and may be variously modified without departing the subject matter of the present disclosure.

The example of using a metal film has been described in the foregoing embodiments, but the present disclosure is not limited thereto and may be applicable to a film type using a process gas containing, in particular, chloride as halide and formed at a temperature of 450 degrees C. or less. The present disclosure may also be applicable, for example, to a metal film such as a TaN film, a WN film or a combination thereof, or an insulating film such as an SiN film, an AlN film, a HfN film, a ZrN film or a combination thereof. In addition, the present disclosure may also be applicable to a combination of the above-described metal film and insulating film.

Also, in case of forming the above-described metal film and insulating film, tantalum pentachloride (TaCl₅), tungsten hexachloride (WCl₆), aluminum trichloride (AlCl₃), hafnium tetrachloride (HfCl₄), zirconium tetrachloride (ZrCl₄) or the like may be used as a process gas containing, in particular, chloride as halide, in addition to TiCl₄.

As a nitriding-reducing agent, a diazene (N₂H₂) gas, a hydrazine (N₂H₄) gas, an N₃H₈ gas, nitrogen (N₂), nitrous oxide (N₂O), monomethylhydrazine (CH₆N₂), dimethylhydrazine (C₂H₈N₂), or the like may be used in addition to the NH₃ gas.

As an inert gas, a rare gas such as an argon (Ar) gas, a helium (He) gas, a neon (Ne) gas, or a xenon (Xe) gas may be used in addition to the N₂ gas.

The foregoing embodiments, modified examples, application examples and the like may be used in an appropriate combination. In addition, the process conditions at this time may be substantially the same as those of the foregoing embodiments as the examples.

The process recipe used for forming these various kinds of thin films (program in which a process order, process conditions and the like are described) may be preferably individually prepared (a plurality of recipes are prepared) according to contents of the substrate processing (a type, a composition ratio, a film quality and a film thickness of a thin film to be formed, a process order, process conditions and the like). In addition, when the substrate processing is initiated, it is preferred that a suitable process recipe is appropriately selected among the plurality of process recipes according to contents of the substrate processing. Specifically, preferably, the plurality of process recipes individually prepared according to the contents of the substrate processing is preferably stored (installed) beforehand in the memory device 121c provided in the substrate processing apparatus via an electrical communication line or a recording medium (e.g., the external memory device 123) in which the corresponding process recipes are recorded. In addition, when the substrate processing is initiated, it is preferred that the CPU 121a provided in the substrate processing apparatus appropriately selects a suitable process recipe among the plurality of process recipes stored in the memory device 121c according to the contents of the substrate processing. With this configuration, multipurpose thin films having a variety of film types, composition ratios, film qualities and film thicknesses can be formed at high reproducibility with one substrate processing apparatus. In addition, it is possible to facilitate manipulation operations performed by an operator (e.g., ease a burden of inputting a process order or process conditions by the operator), and to rapidly initiate the substrate processing while avoiding an operation mistake.

The above-described process recipe is not limited to a newly prepared recipe and may be realized, for example, by modifying a process recipe of an existing substrate processing apparatus. When the process recipe is modified, the process recipe according to the present disclosure may be installed on the existing substrate processing apparatus via an electrical communication line or a recording medium in which the process recipe is recorded. Also, it may be possible to modify the process recipe itself to a process recipe according to the present disclosure by manipulating an input/output device of the existing substrate processing apparatus.

In the foregoing embodiment, the example in which the substrate processing apparatus is a batch type vertical apparatus for processing a plurality of substrates at a time and a film is formed by using a processing furnace having a structure in which nozzles for supplying a process gas are vertically installed in one reaction tube and an exhaust port is installed below the reaction tube has been described, but the present disclosure may also be applicable to a case in which a film is formed by using a processing furnace having a different structure. For example, the present disclosure may also be applicable to a case of forming a film by using a processing furnace having a structure in which two reaction tubes (an outer reaction tube is called an outer tube and an inner reaction tube is called an inner tube) having a concentrically circular section are provided and a process gas flows from a nozzle vertically installed within the inner tube to an exhaust port that is open at a location in a sidewall of the outer tube and opposite to the nozzle with a substrate interposed therebetween (linearly symmetrical location). In addition, the process gas may be supplied via a gas supply hole opened in a sidewall of the inner tube, rather than being supplied from the nozzle vertically installed within the inner tube. In such a case, the exhaust port may be opened in the outer tube according to a height at which a plurality of substrates stacked and accommodated in a process chamber are present. Further, the shape of the exhaust port may have a hole shape or a slit shape.

In the above-described embodiment, the example of forming a film using a batch type vertical substrate processing apparatus in which a plurality of substrates can be processed at a time has been described. However, the present disclosure is not limited thereto and may be appropriately applicable to a case in which a film is formed using a single-wafer type substrate processing apparatus which can process one or several substrates at a time. In addition, in the above-described embodiment, an example of forming a thin film using a substrate processing apparatus having a hot wall type processing furnace has been described. However, the present disclosure is not limited thereto and may be appropriately applicable to a case in which a film is formed using a substrate processing apparatus having a cold wall type processing furnace. Even in these cases, process conditions may be the same as those in the above-described embodiment as the example.

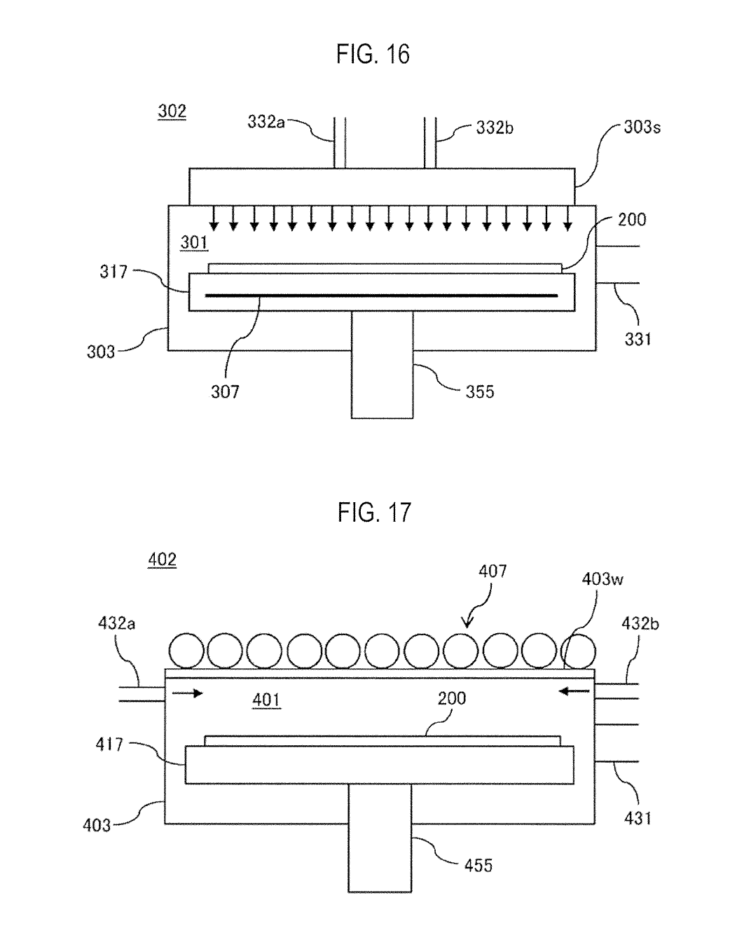

For example, the present disclosure may be appropriately applicable to a case in which a film is formed using a substrate processing apparatus having a processing furnace 302 shown in FIG. 16. The processing furnace 302 includes a process vessel 303 forming a process chamber 301, a shower head 303s supplying a gas in the form of a shower into the process chamber 301, a support table 317 configured to support one or several wafers 200 in a horizontal posture, a rotation shaft 355 configured to support the support table 317 from a bottom end of the support table 317, and a heater 307 installed in the support table 317. An inlet (gas introduction port) of the shower head 303s is connected with a gas supply port 332a for supplying the above-described precursor gas and a gas supply port 332b for supplying the above-described reaction gas. The gas supply port 332a is connected with a precursor gas supply system like the precursor gas supply system in the above-described embodiment. The gas supply port 332b is connected with a reaction gas supply system like the reaction gas supply system in the above-described embodiment. A gas distribution plate for supplying a gas in the form of a shower into the process chamber 301 is installed in an outlet (gas discharging port) of the shower head 303s. An exhaust port 331 for exhausting the interior of the process chamber 301 is installed in the process vessel 303. The exhaust port 331 is connected with an exhaust system like the exhaust system in the above-described embodiment.

In addition, for example, the present disclosure may be appropriately applicable to a case in which a film is formed using a substrate processing apparatus having a processing furnace 402 shown in FIG. 17. The processing furnace 402 includes a process vessel 403 forming a process chamber 401, a support table 417 configured to support one or several wafers 200 in a horizontal posture, a rotation shaft 455 configured to support the support table 417 from a bottom end of the support table 417, a lamp heater 407 configured to irradiate light toward the wafers 200 in the process vessel 403, and a quartz window 403w allowing the light irradiated from the lamp heater 407 to transmit therethrough. The process vessel 403 is connected with a gas supply port 432a for supplying the above-described precursor gas and a gas supply port 432b for supplying the above-described reaction gas. The gas supply port 432a is connected with a precursor gas supply system like the precursor gas supply system in the above-described embodiment. The gas supply port 432b is connected with a reaction gas supply system like the reaction gas supply system in the above-described embodiment. An exhaust port 431 for exhausting the interior of the process chamber 401 is installed in the process vessel 403. The exhaust port 431 is connected with an exhaust system like the exhaust system in the above-described embodiment.

Even when these substrate processing apparatuses are used, a film forming process can be performed with the same sequence and process conditions as the above-described embodiments and modifications.

Hereinafter, preferred aspects of the present disclosure will be supplemented.

### (Supplementary Note 1)

According to further another aspect of the present disclosure, there is provided a method of manufacturing a semiconductor device or a substrate processing method, including forming a film on the substrate by performing a predetermined number of times a cycle including: supplying a first process gas to a substrate; and supplying a second process gas to the substrate, wherein the act of supplying the first process gas and the act of supplying the second process gas are performed in a state where a temperature of the substrate is maintained at a predetermined temperature of room temperature or more and 450 degrees C. or less; and a third process gas, which reacts with byproducts produced by a reaction of the first process gas and the second process gas, is supplied to the substrate simultaneously with at least one of the act of supplying the first process gas and the act of supplying the second process gas.

### (Supplementary Note 2)

In the method of manufacturing a semiconductor device or the substrate processing method according to Supplementary Note 1, the byproducts are chloride.

### (Supplementary Note 3)

In the method of manufacturing a semiconductor device or the substrate processing method according to Supplementary Note 2, the third process gas reacts with the byproducts to generate salt.

### (Supplementary Note 4)

In the method of manufacturing a semiconductor device or the substrate processing method according to any one of Supplementary Notes 1 to 3, when the third process gas is supplied to the substrate simultaneously with the act of supplying the first process gas, a time duration for which the third process gas is supplied to the substrate is set to be longer than that for which the act of supplying a first process gas is performed.

### (Supplementary Note 5)

In the method of manufacturing a semiconductor device or the substrate processing method according to Supplementary Note 4, when the third process gas is supplied to the substrate simultaneously with the act of supplying the first process gas, the supply of the first process gas starts and then stops while the third process gas is supplied to the substrate.

### (Supplementary Note 6)

In the method of manufacturing a semiconductor device or the substrate processing method according to any one of Supplementary Notes 1 to 3, when the third process gas is supplied to the substrate simultaneously with the act of supplying the second process gas, a time duration for which the third process gas is supplied to the substrate is set to be longer than that for which the act of supplying a second process gas is performed.

### (Supplementary Note 7)

In the method of manufacturing a semiconductor device or the substrate processing method according to Supplementary Note 6, when the third process gas is supplied to the substrate simultaneously with the act of supplying the second process gas, the supply of the second process gas starts and then stops while the third process gas is supplied to the substrate.

### (Supplementary Note 8)

In the method of manufacturing a semiconductor device or the substrate processing method according to any one of Supplementary Notes 1 to 3, when the third process gas is supplied to the substrate simultaneously with the act of supplying the first process gas, a time duration for which the third process gas is supplied to the substrate is set to be equal to that for which the act of supplying the first process gas is performed.

### (Supplementary Note 9)

In the method of manufacturing a semiconductor device or the substrate processing method according to any one of Supplementary Notes 1 to 3, when the third process gas is supplied to the substrate simultaneously with the act of supplying the second process gas, a time duration for which the third process gas is supplied to the substrate is set to be equal to that for which the act of supplying the second process gas is performed.

### (Supplementary Note 10)

In the method of manufacturing a semiconductor device or the substrate processing method according to any one of Supplementary Notes 1 to 3, when the third process gas is supplied to the substrate simultaneously with the act of supplying the first process gas, at least one of a timing at which the supply of the first process gas starts and a timing at which the supply of the third process gas starts, or a timing at which the supply of the first process gas is stopped and a timing at which the supply of the third process gas is stopped, with respect to the substrate, is set to be the same timing.

### (Supplementary Note 11)

In the method of manufacturing a semiconductor device or the substrate processing method according to any one of Supplementary Notes 1 to 3, when the third process gas is supplied to the substrate simultaneously with the act of supplying the second process gas, at least one of a timing at which the supply of the second process gas starts and a timing at which the supply of the third process gas starts, or a timing at which the supply of the second process gas is stopped and a timing at which the supply of the third process gas is stopped, with respect to the substrate, is set to be the same timing.

### (Supplementary Note 12)

In the method of manufacturing a semiconductor device or the substrate processing method according to any one of Supplementary Notes 1 to 11, the act of supplying the first process gas, the act of supplying the second process gas, and the act of supplying the third process gas are performed in a state where the substrate is maintained at a predetermined temperature of room temperature or more and 450 degrees C. or less.

### (Supplementary Note 13)

In the method of manufacturing a semiconductor device or the substrate processing method according to any one of Supplementary Notes 1 to 12, the film is a metal nitride film.

### (Supplementary Note 14)

In the method of manufacturing a semiconductor device or the substrate processing method according to any one of Supplementary Notes 1 to 13, the first process gas is chloride.

### (Supplementary Note 15)

In the method of manufacturing a semiconductor device or the substrate processing method according to Supplementary Note 14, the first process gas is TiCl₄ and the second process gas is NH₃.

### (Supplementary Note 16)

In the method of manufacturing a semiconductor device or the substrate processing method according to any one of Supplementary Notes 1 to 15, the byproducts are HCl or NHₓCl.

### (Supplementary Note 17)

In the method of manufacturing a semiconductor device or the substrate processing method according to any one of Supplementary Notes 1 to 16, the third process gas is C₅H₅N.

### (Supplementary Note 18)

According to another aspect of the present disclosure, there is provided a method of manufacturing a semiconductor device or a substrate processing method, including forming a film on a substrate by performing a predetermined number of times a cycle including: supplying a first process gas to the substrate; and supplying a second process gas to the substrate, wherein the act of supplying the first process gas and the act of supplying the second process gas are performed in a state where the substrate is maintained at a predetermined temperature of room temperature or more and 450 degrees C. or less, and a third process gas, which reacts with byproducts produced by a reaction of the first process gas and the second process gas, is supplied to the substrate after at least one of the act of supplying the first process gas or the act of supplying the second process gas.

### (Supplementary Note 19)

According to further another aspect of the present disclosure, there is provided a method of manufacturing a semiconductor device or a substrate processing method, including forming a film on the substrate by performing a cycle including: supplying a first process gas and a second process gas to a substrate a predetermined number of times in a time-division manner (asynchronously, intermittently, or in a pulse-wise manner), wherein a third process gas, which reacts with byproducts produced by reaction of the first process gas and the second process gas, is supplied to the substrate continuously; the act of supplying the first process gas and the act of supplying the second process gas are performed in a state where the substrate is maintained at a predetermined temperature of room temperature or more and 450 degrees C. or less; and the act of supplying the first process gas and the second process gas is performed simultaneously with the act of supplying the third process gas.

### (Supplementary Note 20)

According to further another aspect of the present disclosure, there is provided a substrate processing apparatus, including: a process chamber configured to accommodate a substrate; a heating system configured to heat the substrate; a first process gas supply system configured to supply a first process gas to the substrate; a second process gas supply system configured to supply a second process gas to the substrate; a third process gas supply system configured to supplying a third process gas, which reacts with byproducts produced by reaction of the first process gas and the second process gas, to the substrate; and a control part configured to control the heating system, the first process gas supply system, the second process gas supply system, and the third process gas supply system, wherein the control part is configured such that the act of supplying the first process gas to the substrate accommodated in the process chamber and the act of supplying the second process gas to the substrate are performed a predetermined number of times to form a film on the substrate; the act of supplying the first process gas and the act of supplying the second process gas are performed in a state where the substrate is maintained at a predetermined temperature of room temperature or more and 450 degrees C. or less; and the third process gas is supplied to the substrate simultaneously with at least one of the act of supplying the first process gas or the act of supplying the second process gas.

### (Supplementary Note 21)

According to further another aspect of the present disclosure, there is provided a substrate processing apparatus, including: a process chamber configured to accommodate a substrate; a heating system configured to heat the substrate; a first process gas supply system configured to supply a first process gas to the substrate; a second process gas supply system configured to supply a second process gas to the substrate; a third process gas supply system configured to supplying a third process gas, which reacts with byproducts produced by reaction of the first process gas and the second process gas, to the substrate; and a control part configured to control the heating system, the first process gas supply system, the second process gas supply system, and the third process gas supply system, wherein the control part is configured such that the act of supplying the first process gas to the substrate accommodated in the process chamber and the act of supplying the second process gas to the substrate are performed a predetermined number of times to form a film on the substrate; the act of supplying the first process gas and the act of supplying the second process gas are performed in a state where the substrate is maintained at a predetermined temperature of room temperature or more and 450 degrees C. or less; and the third process gas is supplied to the substrate after at least one of the act of supplying the first process gas of the act of supplying the second process gas is performed.

### (Supplementary Note 22)

According to still another aspect of the present disclosure, there is provided a substrate processing apparatus, including: a process chamber configured to accommodate a substrate; a heating system configured to heat the substrate; a first process gas supply system configured to supply a first process gas to the substrate; a second process gas supply system configured to supply a second process gas to the substrate; a third process gas supply system configured to supplying a third process gas, which reacts with byproducts produced by reaction of the first process gas and the second process gas, to the substrate; and a control part configured to control the heating system, the first process gas supply system, the second process gas supply system, and the third process gas supply system, wherein the control part is configured such that the act of supplying the first process gas to the substrate accommodated in the process chamber and the act of supplying the second process gas to the substrate are performed a predetermined number of times in a time-division manner (asynchronously, intermittently, or in a pulse-wise manner) to form a film on the substrate; the third process gas is supplied to the substrate continuously; the act of supplying the first process gas and the act of supplying the second process gas are performed in a state where the substrate is maintained at a predetermined temperature of room temperature or more and 450 degrees C. or less; and the act of supplying the first process gas and the second process gas are performed simultaneously with the act of supplying the third process gas.

### (Supplementary Note 23)

According to still another aspect of the present disclosure, there is provided a program that causes a computer to perform a process and a non-transitory computer-readable recording medium storing the program, the process including forming a film on the substrate by performing a predetermined number of times: supplying a first process gas to a substrate; and supplying a second process gas to the substrate, wherein the act of supplying the first process gas and the act of supplying the second process gas are performed in a state where the substrate is maintained at a predetermined temperature of room temperature or more and 450 degrees C. or less; and a third process gas, which reacts with byproducts produced by reaction of the first process gas and the second process gas, is supplied to the substrate simultaneously with at least one of the act of supplying the first process gas or the act of supplying the second process gas.

### (Supplementary Note 24)

According to further another aspect of the present disclosure, there is provided a program that causes a computer to perform a process and a non-transitory computer-readable recording medium storing the program, the process including forming a film on the substrate by performing a predetermined number of times: supplying a first process gas to a substrate; and supplying a second process gas to the substrate, wherein the act of supplying the first process gas and the act of supplying a second process gas are performed in a state where the substrate is maintained at a predetermined temperature of room temperature or more and 450 degrees C. or less; and a third process gas, which reacts with byproducts produced by reaction of the first process gas and the second process gas, is supplied to the substrate after at least one of the act of supplying the first process gas or the act of supplying a second process gas is performed.

### (Supplementary Note 25)

According to still another aspect of the present disclosure, there is provided a program that causes a computer to perform a process and a non-transitory computer-readable recording medium storing the program, the process including forming a film on the substrate by performing: supplying a first process gas and a second process gas to a substrate a predetermined number of times in a time-division manner (asynchronously, intermittently, or in a pulse-wise manner), wherein a third process gas, which reacts with byproducts produced by reaction of the first process gas and the second process gas, is supplied to the substrate continuously; the act of supplying a first process gas and the act of supplying a second process gas are performed in a state where the substrate is maintained at a predetermined temperature of room temperature or more and 450 degrees C. or less; and the act of supplying the first process gas and the second process gas is performed simultaneously with the act of supplying a third process gas.

According to the present disclosure in some embodiments, it is possible to provide a technique capable of discharging byproducts produced when a thin film is formed to the outside of a process chamber.

While certain embodiments have been described, these embodiments have been presented by way of example only, and are not intended to limit the scope of the disclosures. Indeed, the novel methods and apparatuses described herein may be embodied in a variety of other forms; furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A method of manufacturing a semiconductor device, comprising foil ling a film on a substrate by performing a predetermined number times a cycle including:
supplying a first process gas to the substrate; and
supplying a second process gas to the substrate,
wherein the act of supplying a first process gas and the act of supplying a second process gas are performed in a state where the substrate is maintained at a predetermined temperature of room temperature or more and 450 degrees C. or less, and
a third process gas, which reacts with byproducts produced by a reaction of the first process gas and the second process gas, is supplied to the substrate simultaneously with at least one of the act of supplying a first process gas and the act of supplying a second process gas.

2. The method of claim 1, wherein the byproducts are chloride.

3. The method of claim 2, wherein the third process gas reacts with the byproducts to generate salt.

4. The method of claim 1, wherein when the third process gas is supplied to the substrate simultaneously with the act of supplying a first process gas, a time duration for which the third process gas is supplied to the substrate is set to be longer than a time duration for which the act of supplying a first process gas is performed.

5. The method of claim 4, wherein when the third process gas is supplied to the substrate simultaneously with the act of supplying a first process gas, the supply of the first process gas starts and then stops while the third process gas is supplied to the substrate.

6. The method of claim 1, wherein when the third process gas is supplied to the substrate simultaneously with the act of supplying a second process gas, a time duration for which the third process gas is supplied to the substrate is set to be longer than a time duration for which the act of supplying a second process gas is performed.

7. The method of claim 6, wherein when the third process gas is supplied to the substrate simultaneously with the act of supplying a second process gas, the supply of the second process gas starts and then stops while the third process gas is supplied to the substrate.

8. The method of claim 1, wherein when the third process gas is supplied to the substrate simultaneously with the act of supplying a first process gas, a time duration for which the third process gas is supplied to the substrate is set to be equal to a time duration for which the act of supplying a first process gas is performed.

9. The method of claim 1, wherein when the third process gas is supplied to the substrate simultaneously with the act of supplying a second process gas, a time duration for which the third process gas is supplied to the substrate is set to be equal to a time duration for which the act of supplying a second process gas is performed.

10. The method of claim 1, wherein when the third process gas is supplied to the substrate simultaneously with the act of supplying a first process gas, at least one of a timing at which the supply of the first process gas starts and a timing at which the supply of the third process gas starts, or a timing at which the supply of the first process gas is stopped and a timing at which the supply of the third process gas is stopped, with respect to the substrate, is set to be the same timing.

11. The method of claim 1, wherein when the third process gas is supplied to the substrate simultaneously with the act of supplying a second process gas, at least one of a timing at which the supply of the second process gas starts and a timing at which the supply of the third process gas starts, or a timing at which the supply of the second process gas is stopped and a timing at which the supply of the third process gas is stopped, with respect to the substrate, is set to be the same timing.

12. The method of claim 1, wherein the first process gas is a metal-containing chloride, the second process gas is a nitriding gas, the byproducts are HCl or NHₓCl, and the film is a metal nitride film.

13. A method of manufacturing a semiconductor device, comprising forming a film on a substrate by performing a predetermined number of times a cycle including:
supplying a first process gas to the substrate; and
supplying a second process gas to the substrate,
wherein the act of supplying a first process gas and the act of supplying a second process gas are performed in a state where the substrate is maintained at a predetermined temperature of room temperature or more and 450 degrees C. or less, and
a third process gas, which reacts with byproducts produced by a reaction of the first process gas and the second process gas, is supplied to the substrate after at least one of the act of supplying a first process gas and the act of supplying a second process gas.

14. A substrate processing apparatus, comprising:
a process chamber configured to accommodate a substrate;
a heating system configured to heat the substrate;
a first process gas supply system configured to supply a first process gas to the substrate;
a second process gas supply system configured to supply a second process gas to the substrate;
a third process gas supply system configured to supply a third process gas, which reacts with byproducts produced by a reaction of the first process gas and the second process gas, to the substrate; and
a control part configured to control the heating system, the first process gas supply system, the second process gas supply system, and the third process gas supply system,
wherein the control part is configured such that the act of supplying a first process gas to the substrate accommodated in the process chamber and the act of supplying a second process gas to the substrate are performed a predetermined number of times to form a film on the substrate; the act of supplying a first process gas and the act of supplying a second process gas are performed in a state where the substrate is maintained at a predetermined temperature of room temperature or more and 450 degrees C. or less; and the third process gas is supplied to the substrate simultaneously with at least one of the act of supplying a first process gas and the act of supplying a second process gas.
